(19) United States
(12) Patent Application Publication
(10) Pub. No.: US 2025/0071966 A1
(43) Pub. Date: Feb. 27, 2025

(54) SEMICONDUCTOR DEVICE AND METHOD FOR FABRICATING THE SAME

(71) Applicant: SK hynix Inc., Gyeonggi-do (KR)

(72) Inventors: Seung Hwan KIM, Gyeonggi-do (KR); Gil Seop KIM, Gyeonggi-do (KR); Hye Won YOON, Gyeonggi-do (KR)

(21) Appl. No.: 18/581,384

(22) Filed: Feb. 20, 2024

(30) Foreign Application Priority Data
Aug. 21, 2023 (KR) 10-2023-0109068

(51) Int. Cl. H10B 12/00

(52) U.S. Cl. CPC H10B 12/03; H10B 12/315; H10B 12/482

(57) ABSTRACT

A method for fabricating a semiconductor device includes forming a stack body including a plurality of recess target layers over a lower structure; forming sacrificial isolation openings in the stack body; forming sacrificial isolation layers in the sacrificial isolation openings; forming sacrificial vertical openings having bottom surfaces disposed at a lower level than bottom surfaces of the sacrificial isolation openings in the stack body between the sacrificial isolation layers; forming preliminary horizontal layers by recessing the recess target layers through the sacrificial vertical openings; forming sacrificial pillar structures that fill the sacrificial vertical openings; forming cell isolation openings by removing the sacrificial isolation layers; forming horizontal layers by trimming the preliminary horizontal layers through the cell isolation openings; and forming cell isolation layers that fill the cell isolation openings.

### CROSS-REFERENCE TO RELATED APPLICATIONS

The present application claims priority under 35 U.S.C 119(a) to Korean Patent Application No. 10-2023-0109068, filed on Aug. 21, 2023, which is incorporated herein by reference in its entirety.

### BACKGROUND

### 1. Field

Various embodiments of the present invention relate to a semiconductor device, and more particularly, to a semiconductor device including memory cells that are arranged in three dimensions, and a method for fabricating the semiconductor device.

### 2. Description of the Related Art

Recently, in order to cope with the demands for large capacity and miniaturization of memory devices, a technology for providing a three-dimensional (3D) memory device in which a plurality of memory cells are stacked has been proposed.

### SUMMARY

Embodiments of the present invention are directed to a semiconductor device including highly integrated memory cells, and a method for fabricating the semiconductor device.

In accordance with an embodiment of the present invention, a method for fabricating a semiconductor device includes: forming a stack body including a plurality of recess target layers over a lower structure; forming sacrificial isolation openings in the stack body; forming sacrificial isolation layers in the sacrificial isolation openings; forming sacrificial vertical openings having bottom surfaces disposed at a lower level than bottom surfaces of the sacrificial isolation openings in the stack body between the sacrificial isolation layers; forming preliminary horizontal layers by recessing the recess target layers through the sacrificial vertical openings; forming sacrificial pillar structures that fill the sacrificial vertical openings; forming cell isolation openings by removing the sacrificial isolation layers; forming horizontal layers by trimming the preliminary horizontal layers through the cell isolation openings; and forming cell isolation layers that fill the cell isolation openings.

In accordance with another embodiment of the present invention, a method for fabricating a semiconductor device includes: forming a stack body including a plurality of sub-stacks over a lower structure;

forming sacrificial isolation openings in the stack body; forming sacrificial isolation layers in the sacrificial isolation openings; forming sacrificial vertical openings having bottom surfaces disposed at lower levels than the sacrificial isolation openings in the stack body between the sacrificial isolation layers; forming sacrificial pillar structures that fill the sacrificial vertical openings; forming cell isolation openings by removing the sacrificial isolation layers; expanding the cell isolation openings to form supporters that support the sacrificial pillar structures; and forming cell isolation layers that fill the expanded cell isolation openings.

In accordance with another embodiment of the present invention, a semiconductor device includes: cell isolation layers vertically oriented in a first direction; horizontal layers oriented horizontally in a second direction intersecting with the first direction and vertically stacked in the first direction between the cell isolation layers; a vertical conductive line oriented vertically in the first direction and coupled to first edges of the horizontal layers; horizontal conductive lines crossing each of the horizontal layers in a third direction intersecting with the first direction and the second direction; data storage elements respectively coupled to second edges of the horizontal layers; and supporters disposed below the vertical conductive line and the data storage elements. Bottom surfaces of the cell isolation layers are disposed at a lower level than bottom surfaces of the vertical conductive lines. Each of the cell isolation layers includes: a lower isolation area disposed between the supporters; and an upper isolation area disposed between the vertical conductive lines, and a horizontal width of the lower isolation area is greater than a horizontal width of the upper isolation area. The supporters and the horizontal layers include monocrystalline silicon. Each of the horizontal conductive lines includes a double-structured horizontal line that faces each other with the horizontal layers respectively interposed therebetween.

In accordance with another embodiment of the present invention, a method for fabricating a semiconductor device includes: forming a stack body including a plurality of sub-stacks over a lower structure; forming sacrificial isolation openings including a bottom surface of a first level in the stack body; forming sacrificial isolation layers in the sacrificial isolation openings; forming sacrificial vertical openings including bottom surfaces of a second level which is higher than the first level in the stack body between the sacrificial isolation layers; expanding the sacrificial vertical openings to have bottom surfaces of a third level which is lower than the second level; forming sacrificial pillar structures that fill the expanded sacrificial vertical openings; forming cell isolation openings by removing the sacrificial isolation layers; expanding the cell isolation openings to have bottom surfaces of a fourth level which is lower than the third level; forming supporters between the expanded cell isolation openings; and forming cell isolation layers that fill the expanded cell isolation openings.

These and other features and advantages of the present invention may be better understood from the following figures and detailed description of specific embodiments of the invention.

### BRIEF DESCRIPTION OF THE DRAWINGS

FIG. 1A is a schematic perspective view illustrating a memory cell in accordance with an embodiment of the present invention.

FIG. 1B is a schematic cross-sectional view illustrating the memory cell shown in FIG. 1A.

FIG. 1C is a plan view illustrating a switching element shown in FIG. 1A.

FIG. 1D is a schematic cross-sectional view illustrating a memory cell in accordance with another embodiment of the present invention.

FIG. 2 is a schematic plan view illustrating a semiconductor device in accordance with an embodiment of the present invention.

FIG. 3A is a schematic perspective view illustrating a first memory cell array MCA1 shown in FIG. 2.

FIG. 3B is a cross-sectional view taken along a line A-A′ shown in FIG. 2.

FIG. 3C is a cross-sectional view taken along a line B-B′ shown in FIG. 2.

FIG. 3D is a cross-sectional view taken along a line B1-B1′ shown in FIG. 2.

FIG. 3E is a cross-sectional view taken along a line C-C′ shown in FIG. 2.

FIGS. 4A to 26B illustrate a method for fabricating a semiconductor device in accordance with an embodiment of the present invention.

FIGS. 27A to 27C are cross-sectional views illustrating a method for fabricating a semiconductor device in accordance with another embodiment of the present invention.

FIGS. 28 to 30 are perspective views illustrating memory cell arrays in accordance with embodiments of the present invention.

### DETAILED DESCRIPTION

Various embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout this disclosure, like reference numerals refer to like parts throughout the various figures and embodiments of the present invention.

The drawings are not necessarily to scale and in some instances, proportions may have been exaggerated to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate. Moreover “overlap’ or “overlapping” as used herein may mean a complete overlap or partial overlap unless further specified. Complete overlap or complete overlapping means that the two structures are entirely covering each other or sharing the same space entirely, with no part of either structure remaining separate from the other. Partial overlap or partial overlapping means that only a portion of one structure or object is overlapping with another.

The following embodiment of the present invention relates to a three-dimensional memory cell, and memory cells may be vertically stacked to increase memory cell density and reduce parasitic capacitance.

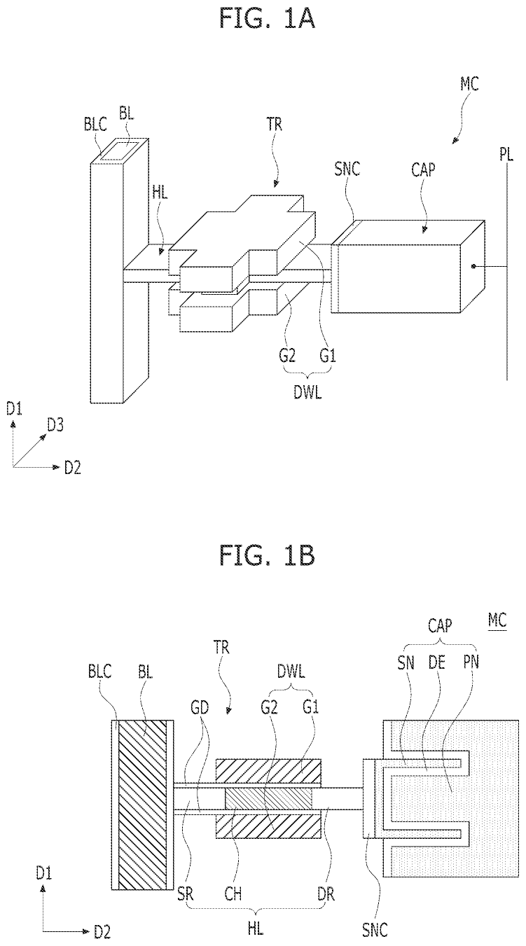

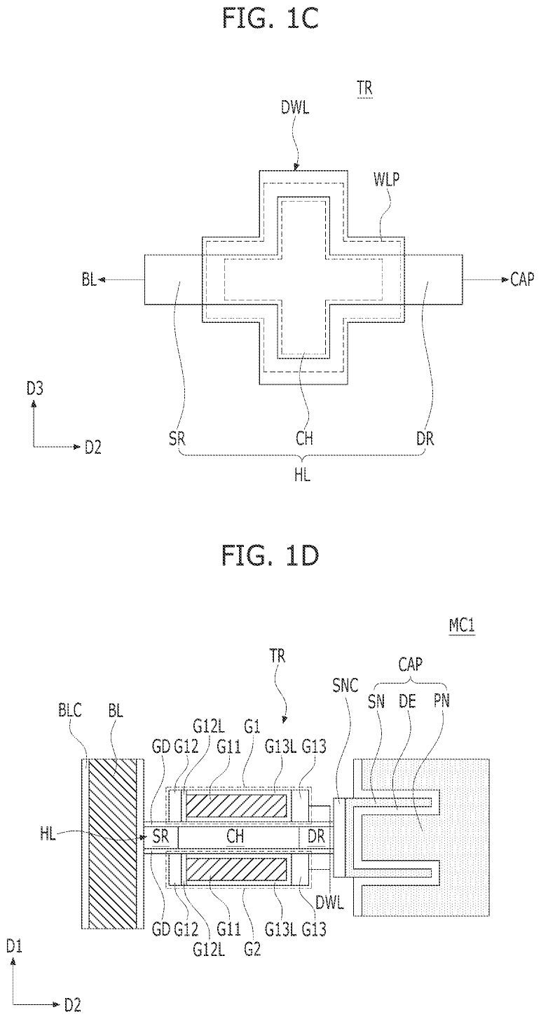

FIG. 1A is a schematic perspective view illustrating a memory cell in accordance with an embodiment of the present invention. FIG. 1B is a schematic cross-sectional view illustrating the memory cell shown in FIG. 1A. FIG. 1C is a plan view illustrating a switching element shown in FIG. 1A.

Referring to FIGS. 1A to 1C, a memory cell MC may include a first conductive line BL, a switching element TR, and a data storage element CAP.

The first conductive line BL may be vertically oriented in a first direction D1. The first conductive line BL may include a bit line. The first conductive line BL may be referred to as a vertical conductive line, a vertically-oriented bit line, a vertically-extending bit line, or a pillar-shaped bit line. The first conductive line BL may include a conductive material. The first conductive line BL may include a silicon-based material, a metal-based material, or a combination thereof. The first conductive line BL may include polysilicon, a metal, a metal nitride, a metal silicide, or a combination thereof. The first conductive line BL may include polysilicon, titanium nitride, tungsten, or a combination thereof. For example, the first conductive line BL may include polysilicon or titanium nitride (TiN) that is doped with an N-type impurity. The first conductive line BL may include a stack of titanium nitride and tungsten (TiN/W).

The switching element TR may have a function of controlling voltage (or current) supply to the data storage element CAP in a data write operation and a data read operation of the data storage element CAP. The switching element TR may include a horizontal layer HL, an inter-level dielectric layer GD, and a second conductive line DWL. The second conductive line DWL may include a horizontal conductive line or a word line, and the horizontal layer HL may include an active layer. The switching element TR may include a transistor, and in this case, the second conductive line DWL may serve as a gate electrode. The switching element TR may also be referred to as an access element or a selection element. The second conductive line DWL may be referred to as a horizontal gate electrode or a horizontal word line.

The horizontal layer HL may extend in a second direction D2 intersecting with the first direction D1. The second conductive line DWL may extend in a third direction D3 intersecting with the first and second directions D1 and D2. The first direction D1 may be a vertical direction, and the second direction D2 may be a first horizontal direction, and the third direction D3 may be a second horizontal direction. The horizontal layer HL may extend in a first horizontal direction (i.e., the second direction D2), and the second conductive line DWL may extend in a second horizontal direction (i.e., the third direction D3).

The horizontal layer HL may be horizontally oriented in the second direction D2 from the first conductive line BL. The second conductive line DWL may have a double structure. For example, the second conductive line DWL may include an upper horizontal line G1 and a lower horizontal line G2 that are facing each other with the horizontal layer HL interposed therebetween. An inter-level dielectric layer GD may be formed on the upper and bottom surfaces of the horizontal layer HL. The upper horizontal line G1 may be disposed over the horizontal layer HL, and the lower horizontal line G2 may be disposed below the horizontal layer HL. The second conductive line DWL may include a pair of an upper horizontal line G1 and a lower horizontal line G2. In the second conductive line DWL, the same driving voltage may be applied to the upper horizontal line G1 and the lower horizontal line G2. For example, an upper horizontal line G1 and a lower horizontal line G2 may form a pair to be coupled to one memory cell MC. According to another embodiment of the present invention, different driving voltages may be applied to the upper horizontal line G1 and the lower horizontal line G2. In this case, one of the upper horizontal line G1 and the lower horizontal line G2 may serve as a back gate or a shield gate.

Referring back to FIG. 1C, each of the upper horizontal line G1 and the lower horizontal line G2 may have a width in the second direction D2, for example, the width of an overlapping portion that overlaps with the horizontal layer HL, which is greater than the width of a portion that does not overlap with the horizontal layer HL. Due to this difference in the widths, the second conductive line DWL may have a notch-shaped sidewall. The second conductive line DWL may include a channel overlapping portion WLP and a channel non-overlapping portion NOL. The channel overlapping portion WLP may refer to a portion that overlaps with the channel CH of the horizontal layer HL, and the channel non-overlapping portion NOL may refer to a portion that does not overlap with the horizontal layer HL. The channel overlapping portion WLP may have a cross shape or a rhombus shape.

From the perspective of a top view, the horizontal layer HL may have a cross shape or a rhombus shape. According to another embodiment of the present invention, the side surfaces of the horizontal layer HL may have a bent shape or a rounded shape.

The horizontal layer HL may include a semiconductor material.

For example, the horizontal layer HL may include polysilicon, monocrystalline silicon, germanium, or silicon-germanium. According to another embodiment of the present invention, the horizontal layer HL may include an oxide semiconductor material. For example, the oxide semiconductor material may include indium gallium zinc oxide (IGZO). According to another embodiment of the present invention, the horizontal layer HL may include a conductive metal oxide.

The upper and bottom surfaces of the horizontal layer HL may have flat surfaces. The upper and bottom surfaces of the horizontal layer HL may be parallel to each other in the second direction D2.

The horizontal layer HL may include a channel CH, a first doped region SR between the channel CH and the first conductive line BL, and a second doped region DR between the channel CH and the data storage element CAP. When the horizontal layer HL is formed of an oxide semiconductor material, the channel CH may be formed of an oxide semiconductor material, and the first and second doped regions SR and DR may be omitted. The horizontal layer HL may also be referred to as an active layer or thin-body. The channel overlapping portion WLP of the channel CH and the second conductive line DWL may overlap with each other. The channel CH may have a cross shape or a rhombus shape. The size of the channel overlapping portion WLP of the second conductive line DWL may be greater than that of the channel CH. The channel overlapping portion WLP of the second conductive line DWL may fully overlap with the channel CH.

The first doped region SR and the second doped region DR may be doped with impurities of the same conductivity type. The first doped region SR and the second doped region DR may be doped with a N-type impurity or a P-type impurity. The first doped region SR and the second doped region DR may include at least one impurity selected from arsenic (As), phosphorus (P), boron (B), indium (In), and combinations thereof. The first doped region SR may be coupled to the first conductive line BL, and the second doped region DR may be coupled to the data storage element CAP. The first and second doped regions SR and DR may be referred to as first and second source/drain regions.

The inter-level dielectric layer GD may be disposed between the horizontal layer HL and the second conductive line DWL. The inter-level dielectric layer GD may be referred to as a gate dielectric layer. The inter-level dielectric layer GD may be referred to as a horizontal layer side dielectric layer. The inter-level dielectric layer GD may include silicon oxide, silicon nitride, a metal oxide, a metal oxynitride, a metal silicate, a high-k material, a ferroelectric material, an anti-ferroelectric material or a combination thereof. The inter-level dielectric layer GD may include SiO₂, Si₃N₄, HfO₂, Al₂O₃, ZrO₂, AlON, HfON, HfSiO, HfSiON, HfZrO, or a combination thereof. The inter-level dielectric layer GD may be formed by thermal oxidation of a semiconductor material.

The second conductive line DWL may include a metal-based material, a semiconductor material, or a combination thereof. The second conductive line DWL may include titanium nitride, tungsten, polysilicon, or a combination thereof. For example, the second conductive line DWL may include a TiN/W stack in which titanium nitride and tungsten are sequentially stacked. The second conductive line DWL may include a N-type work function material or a P-type work function material. The N-type work function material may have a low work function of approximately 4.5 eV or less, and the P-type work function material may have a high work function of approximately 4.5 eV or more. The second conductive line DWL may include a stack of a low work function material and a high work function material.

The data storage element CAP may include a memory element, such as a capacitor. The data storage element CAP may be horizontally disposed in the second direction D2 from the switching element TR. The data storage element CAP may include a first electrode SN extending horizontally from the horizontal layer HL in the second direction D2. The data storage element CAP may further include a second electrode PN over the first electrode SN, and a dielectric layer DE between the first electrode SN and the second electrode PN. The first electrode SN, the dielectric layer DE, and the second electrode PN may be horizontally arranged in the second direction D2. The first electrode SN may include an inner space and a plurality of outer surfaces, and the inner space of the first electrode SN may include a plurality of inner surfaces. The outer surfaces of the first electrode SN may include a vertical outer surface and a plurality of horizontal outer surfaces. The vertical outer surface of the first electrode SN may extend vertically in the first direction D1, and the horizontal outer surface of the first electrode SN may extend horizontally in the second or third direction D2 or D3. The inner space of the first electrode SN may be a three-dimensional space. The dielectric layer DE may conformally cover the inner and outer surfaces of the first electrode SN. The second electrode PN may be disposed in the inner space of the first electrode SN over the dielectric layer DE. Some of the outer surfaces of the first electrode SN may be electrically connected to the second doped region DR of the horizontal layer HL. The second electrode PN of the data storage element CAP may be coupled to a common plate PL.

A data storage element CAP may be a three-dimensional structure. The first electrode SN may have a three-dimensional structure, and the first electrode SN may have a horizontal three-dimensional structure which is oriented in the second direction D2. As an example of a three-dimensional structure, the first electrode SN may have a cylindrical shape. The cylindrical shape of the first electrode SN may include a cylindrical inner surface and a cylindrical outer surface. Some of the cylindrical outer surfaces of the first electrode SN may be electrically connected to the second doped region DR of the horizontal layer HL. A dielectric layer DE and a second electrode PN may be disposed on the cylinder inner surfaces of the first electrode SN.

According to another embodiment of the present invention, the first electrode SN may have a pillar shape or a pylinder shape. The pylinder shape may refer to a structure in which a pillar shape and a cylindrical shape are merged.

The first electrode SN and the second electrode PN may include a metal, a noble metal, a metal nitride, a conductive metal oxide, a conductive noble metal oxide, a metal carbide, a metal silicide, or a combination thereof. For example, the first electrode SN and the second electrode PN may include titanium (Ti), titanium nitride (TiN), tantalum (Ta), tantalum nitride (TaN), tungsten (W), tungsten nitride (WN), ruthenium (Ru), ruthenium oxide (RuO₂), iridium (Ir), iridium oxide (IrO₂), platinum (Pt), molybdenum (Mo), molybdenum oxide (MoO), a titanium nitride/tungsten (TiN/W) stack, a tungsten nitride/tungsten (WN/W) stack, or a combination thereof. The second electrode PN may include a combination of a metal-based material and a silicon-based material. For example, the second electrode PN may be a stack of titanium nitride/silicon germanium/tungsten nitride (TiN/SiGe/WN). In the titanium nitride/silicon germanium/tungsten nitride (TiN/SiGe/WN) stack, silicon germanium may be a gap-fill material filling the inside of the first electrode SN, and titanium nitride (TiN) may serve as the second electrode PN of a data storage element CAP, and tungsten nitride may be a low-resistance material.

The dielectric layer DE may be referred to as a capacitor dielectric layer or a memory layer. The dielectric layer DE may include silicon oxide, silicon nitride, a high-k material, or a combination thereof. The high-k material may include hafnium oxide (HfO₂), zirconium oxide (ZrO₂), aluminum oxide (Al₂O₃), lanthanum oxide (La₂O₃), titanium oxide (TiO₂), tantalum oxide (Ta₂O₅), niobium oxide (Nb₂O₅) or strontium titanium oxide (SrTiO₃). According to another embodiment of the present invention, the dielectric layer DE may be formed of a composite layer including two or more layers of the aforementioned high-k materials.

The dielectric layer DE may be formed of zirconium (Zr)-based oxide. The dielectric layer DE may have a stack structure including zirconium oxide (ZrO₂). The dielectric layer DE may include a ZA (ZrO₂/Al₂O₃) stack or a ZAZ (ZrO₂/Al₂O₃/ZrO₂) stack. The ZA stack may have a structure in which aluminum oxide (Al₂O₃) is stacked over zirconium oxide (ZrO₂). The ZAZ stack may have a structure in which zirconium oxide (ZrO₂), aluminum oxide (Al₂O₃), and zirconium oxide (ZrO₂) are sequentially stacked. The ZA stack and the ZAZ stack may be referred to as a zirconium oxide (ZrO₂)-based layer. According to another embodiment of the present invention, the dielectric layer DE may be formed of hafnium (Hf)-based oxide. The dielectric layer DE may have a stack structure including hafnium oxide (HfO₂). The dielectric layer DE may include an HA (HfO₂/Al₂O₃) stack or an HAH (HfO₂/Al₂O₃/HfO₂) stack. The HA stack may have a structure in which aluminum oxide (Al₂O₃) is stacked over hafnium oxide (HfO₂). The HAH stack may have a structure in which hafnium oxide (HfO₂), aluminum oxide (Al₂O₃), and hafnium oxide (HfO₂) are sequentially stacked. The HA stack and the HAH stack may be referred to as a hafnium oxide (HfO₂)-based layer. In the ZA stack, ZAZ stack, HA stack, and HAH stack, aluminum oxide (Al₂O₃) may have a greater bandgap energy than zirconium oxide (ZrO₂) and hafnium oxide (HfO₂). Aluminum oxide (Al₂O₃) may have a lower dielectric constant than zirconium oxide (ZrO₂) and hafnium oxide (HfO₂). Accordingly, the dielectric layer DE may include a stack of a high-k material and a high-bandgap material having a greater bandgap energy than the high-k material. The dielectric layer DE may include silicon oxide (SiO₂) as a high bandgap material other than aluminum oxide (Al₂O₃). Since the dielectric layer DE includes a high bandgap material, leakage current may be suppressed. The high-bandgap material may be thinner than the high-k material. According to another embodiment of the present invention, the dielectric layer DE may include a stacked structure in which a high-k material and a high-bandgap material are alternately stacked. For example, the dielectric layer DE may include a ZAZA (ZrO₂/Al₂O₃/ZrO₂/Al₂O₃) stack, a ZAZAZ (ZrO₂/Al₂O₃/ZrO₂/Al₂O₃/ZrO₂) stack, a HAHA (HfO₂/Al₂O₃/HfO₂/Al₂O₃) stack, or a HAHAH (HfO₂/Al₂O₃/HfO₂/Al₂O₃/HfO₂) stack. In the above stacked structure, aluminum oxide (Al₂O₃) may be thinner than zirconium oxide (ZrO₂) and hafnium oxide (HfO₂).

According to another embodiment of the present invention, the dielectric layer DE may include a high-k material and a high-bandgap material, and the dielectric layer DE may include a laminated structure in which a plurality of high-k materials and a plurality of high-bandgap materials are stacked, or a mixed structure in which a high-k material and a high-bandgap material are inter-mixed with each other.

According to another embodiment of the present invention, the dielectric layer DE may include a ferroelectric material, an anti-ferroelectric material, or a combination thereof. For example, the dielectric layer DE may include hafnium zirconium oxide (HfZrO).

According to another embodiment of the present invention, the dielectric layer DE may include a combination of a high-k material and a ferroelectric material, a combination of a high-k material and an anti-ferroelectric material, a high-k material, or a combination of a ferroelectric material and an anti-ferroelectric material.

According to another embodiment of the present invention, an interface control layer for improving leakage current may be further formed between the first electrode SN and the dielectric layer DE. The interface control layer may include titanium oxide (TiO₂), tantalum oxide (Ta₂O₅), niobium oxide (Nb₂O₅), niobium nitride (NbN), or a combination thereof. The interface control layer may also be formed between the second electrode PN and the dielectric layer DE.

The data storage element CAP may include a three-dimensional capacitor. The data storage element CAP may include a Metal-Insulator-Metal (MIM) capacitor. The data storage element CAP may be replaced with other data storage materials. For example, the data storage material may be a thyristor, a phase change material, a magnetic tunnel junction (MTJ), or a variable resistance material.

For example, the memory cell MC may include a thyristor, and the first conductive line BL may be a cathode line, and the data storage element CAP may be replaced with an anode line. Accordingly, the horizontal layer HL may include four semiconductor layers that are stacked in the second direction D2. The thyristor may include a first diode and a second diode that are coupled serially. When a forward bias of the same voltage is applied to the thyristor, the thyristor may have a high conductance state in which a large amount of current flows or a low conductance state in which a small amount of or no current flows. Each memory cell MC according to the embodiment of the present invention may have a ‘1’ state or a ‘0’ state based on the high conductance state and the low conductance state of the thyristor.

Referring back to FIGS. 1A and 1B, the memory cell MC may further include a first contact node BLC and a second contact node SNC. The first contact node BLC may surround the outer wall of the first conductive line BL. The second contact node SNC may be disposed between the horizontal layer HL and the first electrode SN. The first contact node BLC may include a metal-based material or a semiconductor material. The second contact node SNC may include a metal-based material or a semiconductor material. For example, the first and second contact nodes BLC and SNC may include titanium, titanium nitride, tungsten, or a combination thereof. Also, the first and second contact nodes BLC and SNC may include doped polysilicon, and each of the first doped region SR and the second doped region DR may include the impurities diffused from the first and second contact nodes BLC and SNC.

FIG. 1D is a schematic cross-sectional view illustrating a memory cell in accordance with another embodiment of the present invention. The memory cell MC1 shown in FIG. 1D may be similar to the memory cell MC shown in FIGS. 1A to 1C. Hereinafter, a detailed description on the constituent elements also appearing in FIGS. 1A to 1C may be omitted.

The memory cell MC1 may include a first conductive line BL, a switching element TR, and a data storage element CAP. The switching element TR may include a horizontal layer HL, an inter-level dielectric layer GD, and a second conductive line DWL. The horizontal layer HL may include a first doped region SR, a second doped region DR, and a channel CH. The data storage element CAP may include a first electrode SN, a second electrode PN, and a dielectric layer DE.

The memory cell MC1 may further include a first contact node BLC between the first conductive line BL and the horizontal layer HL, and a second contact node SNC between the horizontal layer HL and the data storage element CAP. The first and second contact nodes BLC and SNC may include doped polysilicon. Each of the first doped region SR and the second doped region DR may include the impurities diffused from the first and second contact nodes BLC and SNC.

The second conductive line DWL may include an upper horizontal line G1 and a lower horizontal line G2. Each of the upper horizontal line G1 and the lower horizontal line G2 may include a first work function electrode G11, a second work function electrode G12, and a third work function electrode G13. The first work function electrode G11, the second work function electrode G12, and the third work function electrode G13 may be horizontally disposed in the second direction D2. The first work function electrode G11, the second work function electrode G12, and the third work function electrode G13 may directly contact each other. The second work function electrode G12 may be disposed adjacent to the first conductive line BL, and the third work function electrode G13 may be disposed adjacent to the data storage element CAP. The horizontal layer HL may have a thickness which is thinner than the thickness of each of the first, second, and third work function electrodes G11, G12, and G13.

The first work function electrode G11, the second work function electrode G12, and the third work function electrode G13 may be formed of materials having different work functions. The first work function electrode G11 may have a higher work function than the second and third work function electrodes G12 and G13. The first work function electrode G11 may include a high work function material. The first work function electrode G11 may have a higher work function than a mid-gap work function of silicon. The second and third work function electrodes G12 and G13 may include a low work function material. The second and third work function electrodes G12 and G13 may have a lower work function than the mid-gap work function of silicon. In other words, the high work function material may have a work function which is higher than approximately 4.5 eV, and the low work function material may have a work function which is lower than approximately 4.5 eV. The first work function electrode G11 may include a metal-based material, and the second and third work function electrodes G12 and G13 may include a semiconductor material.

The second and third work function electrodes G12 and G13 may include doped polysilicon which is doped with an N-type dopant (N-type dopant-doped polysilicon). The first work function electrode G11 may include a metal, a metal nitride, or a combination thereof. The first work function electrode G11 may include tungsten, titanium nitride, or a combination thereof. A barrier material may be further formed between the second and third work function electrodes G12 and G13 and the first work function electrode G11.

According to this embodiment of the present invention, each of the upper and lower horizontal lines G1 and G2 of the second conductive line DWL may include the second work function electrode G12—the first work function electrode G11—the third work function electrode G13 that are horizontally disposed in the second direction D2. The first work function electrode G11 may include a metal, and the second work function electrode G12 and the third work function electrode G13 may include polysilicon.

Each of the upper and lower horizontal lines G1 and G2 of the second conductive line DWL may have a PMP (poly Si-Metal-Poly Si) structure in which polysilicon, a metal, and polysilicon are horizontally disposed in the second direction D2. In the PMP structure, the first work function electrode G11 may be a metal-based material, and the second and third work function electrodes G12 and G13 may be N-type dopant-doped polysilicon, which is polysilicon that is doped with an N-type dopant. The N-type dopant may include phosphorus or arsenic.

A first barrier layer G12L may be disposed between the first work function electrode G11 and the second work function electrode G12. A second barrier layer G13L may be disposed between the first work function electrode G11 and the third work function electrode G13. The first and second barrier layers G12L and G13L may include titanium nitride, tantalum nitride, tungsten nitride, or molybdenum nitride. The second barrier layer G13L may cover a top surface, a bottom surface, and one side surface of the first work function electrode G11.

The first work function electrode G11 may have a greater volume than the second and third work function electrodes G12 and G13, and thus the second conductive line DWL may have a low resistance. The first work function electrodes G11 of the upper and lower horizontal lines G1 and G2 may vertically overlap in the first direction D1 with the horizontal layer HL interposed therebetween. The second and third work function electrodes G12 and G13 of the upper and lower horizontal lines G1 and G2 may vertically overlap in the first direction D1 with the horizontal layer HL interposed therebetween. The overlapping area between the first work function electrode G11 and the horizontal layer HL may be greater than the overlapping area between the second and third work function electrodes G12 and G13 and the horizontal layer HL. The second and third work function electrodes G12 and G13 and the first work function electrode G11 may extend in the third direction D3, and the second and third work function electrodes G12 and G13 and the first work function electrode G11 may directly contact each other.

As described above, each of the upper and lower horizontal lines G1 and G2 may have a triple electrode structure including the first, second and third work function electrodes G11, G12 and G13. The second conductive line DWL may include a pair of first work function electrodes G11, a pair of second work function electrodes G12, and a pair of third work function electrodes G13 that extend in the third direction D3 intersecting with the horizontal layer HL with the horizontal layer HL interposed therebetween. The first work function electrodes G11, the second work function electrodes G12, and the third work function electrodes G13 may vertically overlap with the channel CH.

Each of the second conductive lines DWL may include a channel overlapping portion WLP and a channel non-overlapping portion NOL as illustrated in FIG. 1C. The channel overlapping portions WLP may have a cross shape or a rhombus shape. The channel overlapping portions WLP may fully overlap with the channel CH. The second conductive line DWL extending in the third direction D3 by the channel overlapping portions WLP and the channel non-overlapping portions NOL may have notch-shaped sidewalls. From the perspective of a top view, the notch-shaped sidewalls may be provided by protruding portions by the channel overlapping portions WLP and recessed portions by the channel non-overlapping portions NOL. The channel overlapping portion WLP may include first work function electrodes G11, second work function electrodes G12, and third work function electrodes G13, and the first work function electrodes G11, the second work function electrodes G12 and the third work function electrodes G13 may vertically overlap with the channel CH.

In the second direction D2, the first work function electrode G11 having a high work function may be disposed at the center of the second conductive line DWL, and the second and third work function electrodes G12 and G13 having a low work function may be disposed at both ends of the second conductive line DWL. In this way, it is possible to improve the problem of leakage current, such as Gate Induced Drain Leakage (GIDL).

As the first work function electrode G11 having a high work function is disposed at the center of the second conductive line DWL, the threshold voltage of the switching element TR may be increased. Since the second work function electrode G12 of the second conductive line DWL has a low work function, a low electric field may be formed between the first conductive line BL and the second conductive line DWL. Since the third work function electrode G13 of the second conductive line DWL has a low work function, a low electric field may be formed between the data storage element CAP and the second conductive line DWL.

As described above, the memory cell MC1 may include the second conductive line DWL having a triple work function electrode structure. Each of the upper and lower horizontal lines G1 and G2 of the second conductive line DWL may include a first work function electrode G11, a second work function electrode G12, and a third work function electrode G13. The first work function electrode G11 may overlap with the channel CH, and the second work function electrode G12 may be disposed adjacent to the first conductive line BL and the first doped region SR. The third work function electrode G13 may be disposed adjacent to the data storage element CAP and the second doped region DR. Due to the low work function of the second work function electrode G12, a low electric field may be formed between the second conductive line DWL and the first conductive line BL, thereby reducing leakage current. Due to the low work function of the third work function electrode G13, a low electric field may be formed between the second conductive line DWL and the data storage element CAP, thereby improving leakage current. Due to the high work function of the first work function electrode G11, the high threshold voltage of the switching element TR may be formed, and the formation of the low electric field may reduce the height of the memory cell MC1, which is advantageous in terms of integration.

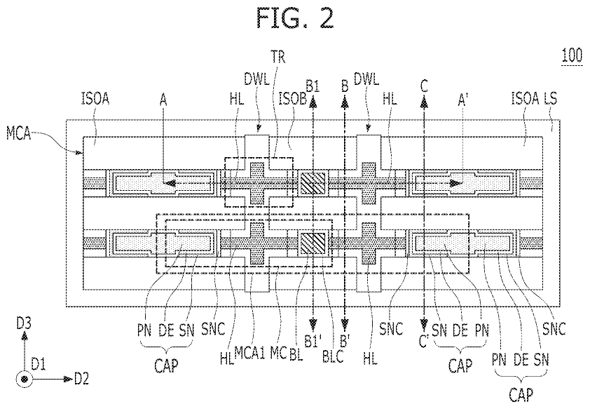

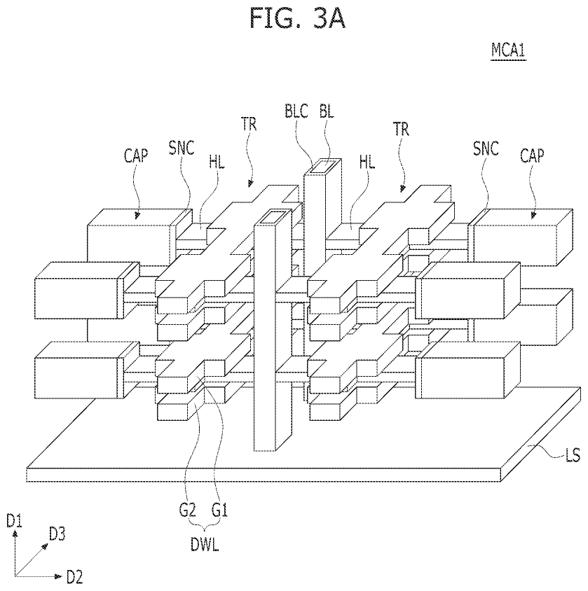

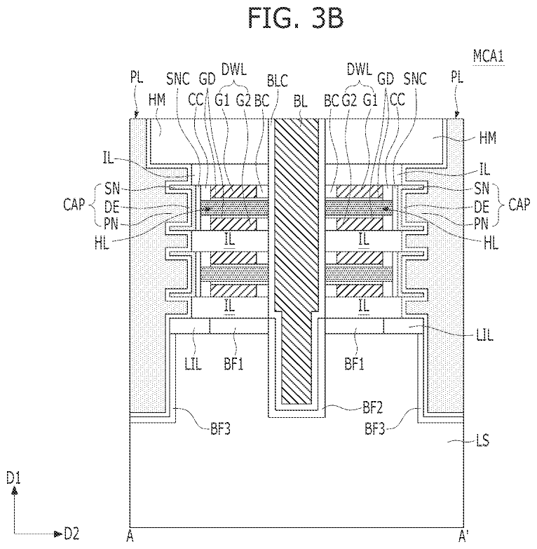

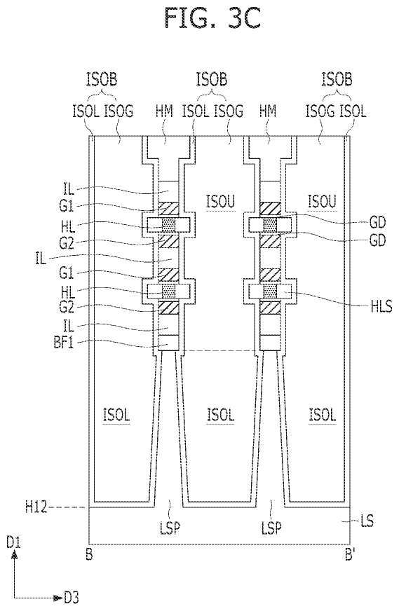

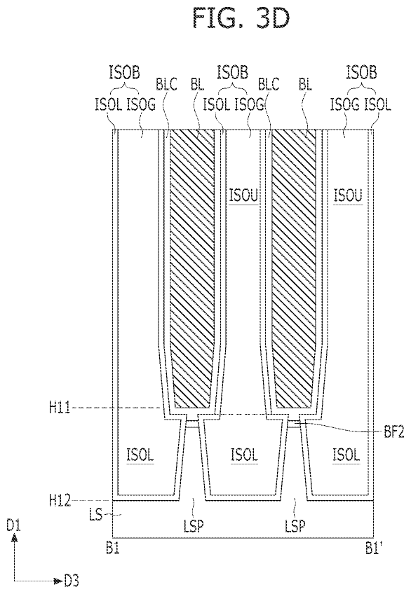

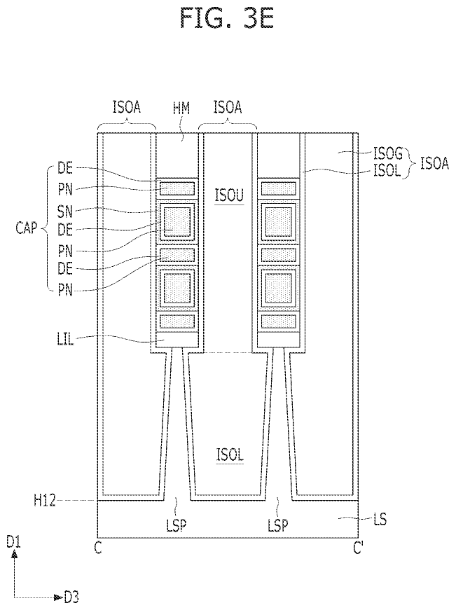

FIG. 2 is a schematic plan view illustrating a semiconductor device in accordance with an embodiment of the present invention. FIG. 3A is a schematic perspective view illustrating a first memory cell array MCA1 shown in FIG. 2. FIG. 3B is a cross-sectional view taken along a line A-A′ shown in FIG. 2. FIG. 3C is a cross-sectional view taken along a line B-B′ shown in FIG. 2. FIG. 3D is a cross-sectional view taken along a line B1-B1′ shown in FIG. 2. FIG. 3E is a cross-sectional view taken along a line C-C′ shown in FIG. 2.

Referring to FIGS. 2, 3A, 3B, 3C, 3D, and 3E, the semiconductor device 100 may include a memory cell array MCA. The memory cell array MCA may include a plurality of memory cells MC. For individual memory cells MC, FIGS. 1A to 1C may be referred to. Each memory cell MC may include a first conductive line BL, a switching element TR, and a data storage element CAP.

A memory cell array MCA may include a three-dimensional array of memory cells MC. The three-dimensional array of memory cells MC may include a column array of memory cells MC and a row array of memory cells MC. The column array of memory cells MC may include a plurality of memory cells MC that are stacked in the first direction D1, and the row array of memory cells MC may be horizontally arranged in the second direction D2 and the third direction D3. The memory cell array MCA may include sub-memory cell arrays MCA1 that are adjacent to each other in the second direction D2. The sub-memory cell array MCA1 may have a mirror-type structure in which two memory cells MC share the first conductive line BL. According to another embodiment of the present invention, the semiconductor device 100 may further include sub-memory cell arrays with a mirror-type structure in which two memory cells MC share the second electrode PN of the data storage element CAP. The memory cell array MCA may include a plurality of sub-memory cell arrays MCA1 in which memory cells MC are vertically stacked in the first direction D1. The memory cell array MCA may include a plurality of sub-memory cell arrays MCA1 that are arranged horizontally in the third direction D3.

Inter-cell dielectric layers IL may be disposed between the memory cells MC that are stacked in the first direction D1. The inter-cell dielectric layers IL may include silicon oxide. The inter-cell dielectric layers IL may be referred to as horizontal inter-cell dielectric layers.

Cell isolation layers ISOA and ISOB may be disposed between the neighboring memory cells MC arranged in the third direction D3. The cell isolation layers ISOA and ISOB may be referred to as vertical inter-cell dielectric layers. The cell isolation layers ISOA and ISOB may include silicon oxide, silicon carbon oxide (SiCO), silicon nitride, or a combination thereof. The cell isolation layers ISOA and ISOB may include first cell isolation layers ISOA and second cell isolation layers ISOB. The first cell isolation layers ISOA and the second cell isolation layers ISOB may extend vertically in the first direction D1. The first cell isolation layers ISOA and the second cell isolation layers ISOB may have a pillar structure extending vertically in the first direction D1. The first cell isolation layers ISOA and the second cell isolation layers ISOB may be alternately and repeatedly disposed in the second direction D2. The first cell isolation layers ISOA may be disposed between the data storage elements CAP in the third direction D3. The second cell isolation layers ISOB may be disposed between the first conductive lines BL in the third direction D3. A second conductive line DWL may be disposed between the first cell isolation layers ISOA and the second cell isolation layers ISOB in the second direction D2. Each of the first cell isolation layers ISOA and the second cell isolation layers ISOB may include a stack of a cell isolation liner layer ISOL and a cell isolation gap-fill layer ISOG. The cell isolation liner layers ISOL may include silicon oxide, and the cell isolation gap-fill layers ISOG may include silicon carbon oxide.

The memory cell array MCA may be disposed over the lower structure LS.

The memory cell array MCA may include a plurality of second conductive lines DWL that are vertically stacked in the first direction D1. The memory cell array MCA may include a plurality of horizontal layers HL that are vertically stacked in the first direction D1. The memory cell array MCA may include a plurality of data storage elements CAP that are vertically stacked in the first direction D1. The memory cell array MCA may include a plurality of first conductive lines BL that are spaced apart from each other in the third direction D3.

Each of the second conductive lines DWL may include a channel overlapping portion WLP and channel non-overlapping portions NOL as illustrated in FIG. 1C. The channel overlapping portion WLP may have a cross shape or a rhombus shape. The channel overlapping portion WLP may fully overlap with the channel CH. The second conductive line DWL extending in the third direction D3 may include a plurality of channel overlapping portions WLP. As the channel overlapping portions WLP and the channel non-overlapping portions NOL are alternately repeated in the third direction D3, the second conductive line DWL may have a notch-shaped sidewall.

A plurality of first passivation layers BF1 may be disposed between the lowermost second conductive line DWL among the second conductive lines DWL and the lower structure LS. A second passivation layer BF2 may be disposed between the first conductive line BL and the lower structure LS. Third passivation layers BF3 may be disposed between the data storage element CAP and the lower structure LS. The first to third passivation layers BF1, BF2, and BF3 may include a dielectric material. The first to third passivation layers BF1, BF2, and BF3 may include silicon oxide. The first to third passivation layers BF1, BF2, and BF3 may electrically disconnect the first conductive line BL, the second conductive lines DWL, and the data storage elements CAP from the lower structure LS. The first to third passivation layers BF1, BF2, and BF3 may be referred to as bottom dielectric layers or bottom passivation layers. The lowermost level inter-cell dielectric layer LIL may be disposed between the first passivation layers BF1 and the data storage element CAP.

The first conductive lines BL may extend vertically from the upper portion of the lower structure LS in the first direction D1. The horizontal layers HL may extend in the second direction D2 intersecting with the first direction D1. The second conductive lines DWL may extend in the third direction D3 intersecting with the first and second directions D1 and D2.

From the perspective of a top view, the horizontal layers HL may have a cross shape or a rhombus shape. According to another embodiment of the present invention, the side surfaces of the horizontal layer HL may have a bent shape or a round shape. As illustrated in FIG. 1B, the horizontal layer HL may include a channel CH, a first doped region SR between the channel CH and the first conductive line BL, and a second doped region DR between the channel CH and the data storage element CAP.

A first capping layer BC may be disposed between the second conductive line DWL and the first conductive line BL. A second capping layer CC may be disposed between the second conductive line DWL and the first electrode SN of the data storage element. The first capping layer BC may be disposed between the upper horizontal line G1 and the first conductive line BL, and the first capping layer BC may be disposed between the lower horizontal line G2 and the first conductive line BL. The second capping layer CC may be disposed between the upper horizontal line G1 and the first electrode SN of the data storage element CAP, and the second capping layer CC may be disposed between the lower horizontal line G2 and the first electrode SN of the data storage element CAP. One memory cell MC may include a pair of first capping layers BC and a pair of second capping layers CC.

The first and second capping layers BC and CC may include a dielectric material. The first and second capping layers BC and CC may include silicon oxide, silicon nitride, silicon carbon oxide, an air gap, or a combination thereof. The first capping layer BC may include silicon oxide, and the second capping layer CC may include a stack of silicon oxide and silicon nitride.

The memory cell MC may further include a first contact node BLC and a second contact node SNC. The first contact node BLC may surround the outer wall of the first conductive line BL. The second contact node SNC may be disposed between the horizontal layer HL and the first electrode SN. The first contact node BLC may include a metal-based material or a semiconductor material. The second contact node SNC may include a metal-based material or a semiconductor material. For example, the first and second contact nodes BLC and SNC may include titanium, titanium nitride, tungsten, or a combination thereof. Also, the first and second contact nodes BLC and SNC may include doped polysilicon, and each of the first doped region SR and the second doped region DR may include impurities diffused from the first and second contact nodes BLC and SNC.

The horizontal layers HL of the switching elements TR disposed horizontally in the third direction D3 may share one second conductive line DWL. The horizontal layers HL of the switching elements TR disposed horizontally in the third direction D3 may be coupled to different first conductive lines BL. The switching elements TR stacked in the first direction D1 may share one first conductive line BL. The switching elements TR disposed horizontally in the third direction D3 may share one second conductive line DWL.

The first cell isolation layers ISOA may be disposed between the first electrodes SN of the data storage elements CAP in the third direction D3. The first electrodes SN may be isolated from each other by the first cell isolation layers ISOA. The second electrodes PN of the data storage elements CAP may be coupled to a common plate PL.

The lower structure LS may include a semiconductor substrate, a metal interconnection structure, a dielectric structure, a conductive structure, a bonding pad structure, another memory or a peripheral circuit unit.

For example, the lower structure LS may include a structure in which a peripheral circuit unit, a metal interconnection structure, and a bonding pad structure are sequentially stacked. The memory cell array MCA and the peripheral circuit unit of the lower structure LS may be coupled by wafer bonding.

The peripheral circuit unit of the lower structure LS may be disposed at a lower level than the memory cell array MCA. This may be referred to as a COP (Cell-Over-Peripheral) structure. The peripheral circuit unit may include at least one control circuit for driving the memory cell array MCA. The at least one control circuit of the peripheral circuit unit may include an N-channel transistor, a P-channel transistor, a CMOS circuit, or a combination thereof. The at least one control circuit of the peripheral circuit unit may include an address decoder circuit, a read circuit, a write circuit, and the like. The at least one control circuit of the peripheral circuit unit may include a planar channel transistor, a recess channel transistor, a buried gate transistor, a fin channel transistor (FinFET), and the like.

For example, the peripheral circuit unit may include sub-word line drivers and a sense amplifier. The first conductive line BL may be coupled to a sense amplifier, and the second conductive lines DWL may be coupled to sub-word line drivers.

According to another embodiment of the present invention, the peripheral circuit unit may be disposed at a higher level than the memory cell array MCA. This may be referred to as POC (Peripheral-over-Cell) structure.

According to another embodiment of the present invention, the memory cell array MCA may include a Dynamic Random Access Memory (DRAM), an embedded DRAM, a NAND memory, a ferroelectric RAM (FeRAM), a Spin-Transfer Torque RAM (STTRAM), a Phase-Change RAM (PCRAM), or a Resistive RAM (ReRAM).

According to another embodiment of the present invention, the individual memory cell MC may be replaced with the memory cell MC1 shown in FIG. 1D.

Referring back to FIGS. 2, 3C, 3D, and 3E, the bottom surfaces of the first conductive lines BL may be disposed at a first level H11, and the bottom surfaces of the first and second cell isolation layers ISOA and ISOB may be disposed at a second level H12. The second level H12 may be at a lower level than the first level H11.

Portions of the lower structure LS, for example, supporters LSP, may be disposed below the first conductive lines BL. The supporters LSP may support the first conductive lines BL and the data storage element CAP. The structural stability of the memory cells MC may be increased by the supporters LSP. The supporters LSP and the lower structure LS may include monocrystalline silicon.

The first and second cell isolation layers ISOA and ISOB may have a bulb-shaped structure. The first and second cell isolation layers ISOA and ISOB may include lower isolation areas ISOL and upper isolation areas ISOU. The supporters LSP may be disposed between the lower isolation areas ISOL. The first conductive lines BL may be disposed between the upper isolation areas ISOU. The data storage elements CAP may be disposed between the upper isolation areas ISOU. The width of the lower isolation areas ISOL in the third direction D3 may be greater than the width of the upper isolation areas ISOU.

As described above, since the bottom surfaces of the first conductive lines BL and the data storage element CAP are at a higher level than the bottom surfaces of the first and second cell isolation layers ISOA and ISOB due to the supporters LSP, it is possible to prevent bunkers that may occur while the first conductive line BL and the data storage element CAP are formed.

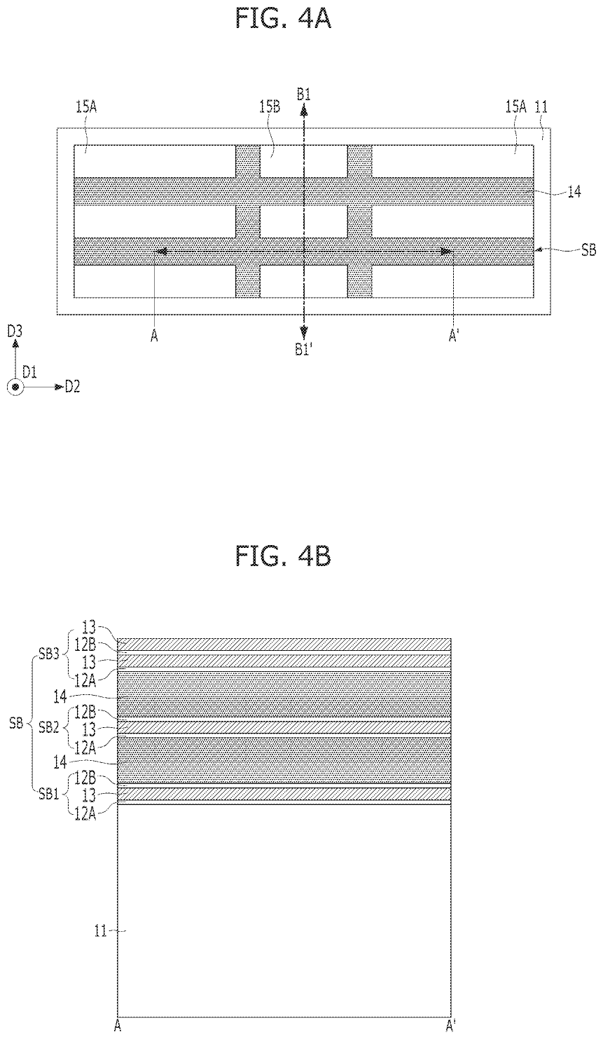

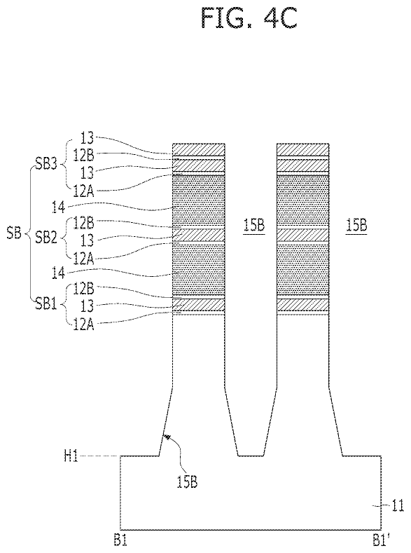

FIGS. 4A to 26B illustrate an example of a method for fabricating a semiconductor device in accordance with an embodiment of the present invention.

FIG. 4A is a plan view of a fourth layer 14 level illustrating a method of forming a stack body SB and sacrificial isolation openings 15A and 15B, and FIG. 4B is a cross-sectional view taken along a line A-A′ shown in FIG. 4A. FIG. 4C is a cross-sectional view taken along a line B1-B1′ shown in FIG. 4A.

Referring to FIGS. 4A to 4C, a stack body SB may be formed over the lower structure 11. The lower structure 11 may comprise a material suitable for semiconductor processing. The lower structure 11 material may include at least one of a conductive material, a dielectric material, and a semiconductive material. Diverse materials may be formed over the lower structure 11. The lower structure 11 may include a semiconductor substrate. The lower structure 11 may be formed of a material containing silicon. The lower structure 11 may include silicon, monocrystalline silicon, polysilicon, amorphous silicon, silicon germanium, monocrystalline silicon germanium, polycrystalline silicon germanium, carbon-doped silicon, a combination thereof, or a multi-layer thereof. The lower structure 11 may also include other semiconductor materials such as germanium. The lower structure 11 may include a III/V-group semiconductor substrate, for example, a compound semiconductor substrate, such as GaAs. The lower structure 11 may include a silicon-on-insulator (SOI) substrate.

In the stack body SB, a plurality of sub-stacks may be alternately stacked. Each of the sub-stacks may include a first layer 12A, a second layer 13, a third layer 12B, and a semiconductor layer 14 that are stacked in the mentioned order. The first layers 12A and the third layers 12B may be formed of the same material and may include silicon germanium. The second layers 13 and the fourth layers 14 may include monocrystalline silicon. The first layers 12A, the second layers 13, the third layers 12B, and the fourth layers 14 may be formed by an epitaxial growth process. The first layer 12A of the lowermost level may serve as a seed layer during the epitaxial growth process. The first layers 12A may be thinner than the second layers 13, and the fourth layers 14 may be thicker than the second layers 13.

The stack body SB may include a plurality of fourth layers 14, a first stack SB1, a second stack SB2, and a third stack SB3. In the stack body SB, the first stack SB1, the fourth layer 14, the second stack SB2, the fourth layer 14, and the third stack SB3 may be stacked in the mentioned order. The second layer 13 may be disposed as the uppermost layer of the stack body SB. Each of the first stack SB1, the second stack SB2, and the third stack SB3 may be a three-layer stack of the first layer 12A/second layer 13/third layer 12B. For example, when the first layers 12A and the third layers 12B include a silicon germanium layer and the second layers 13 include a monocrystalline silicon layer, the first stack SB1, the second stack SB2 and the third stack SB3 may include a stack of first silicon germanium/monocrystalline silicon/second silicon germanium (SiGe/Si/SiGe).

The second layers 13 may include a first monocrystalline silicon layer, and the fourth layers 14 may include a second monocrystalline silicon layer. The second monocrystalline silicon layers may be thicker than the first monocrystalline silicon layers. Accordingly, in the stack body SB, the first stack SB1 may be disposed below the second monocrystalline silicon layers, and the second stack SB2 may be disposed over the second monocrystalline silicon layers. Each of the first and second stacks SB1 and SB2 may include a stack of a first silicon germanium layer/first monocrystalline silicon layer/second silicon germanium layer, and the second monocrystalline silicon layers may be thicker than the first monocrystalline silicon layers.

The first layers 12A, the second layers 13, and the third layers 12B may be referred to as ‘sacrificial layers’, and the fourth layers 14 may be referred to as ‘recess target layers’.

The stack body SB may be referred to as a vertical stack. The stack body SB may be formed by alternating a plurality of sacrificial layers and the recess target layers. The sacrificial layers may include a first stack SB1, a second stack SB2, and a third stack SB3, and each of the first stack SB1, the second stack SB2, and the third stack SB3 may include a stack of the first layer 12A/second layer 13/third layer 12B. The recess target layers may include fourth layers 14. Each of the sacrificial layers may include a stack of a first silicon germanium layer/first monocrystalline silicon layer/second silicon germanium layer, and each of the recess target layers may include a second monocrystalline silicon layer, wherein the second monocrystalline silicon layer may be thicker than the first monocrystalline silicon layers.

As illustrated in FIGS. 2 to 3D described above, when the memory cells MC are vertically stacked, the first stack SB1, the fourth layer 14, the second stack SB2, the fourth stack 14, and the third stack SB3 may be alternately stacked several times.

Subsequently, portions of the stack body SB may be etched to form a plurality of sacrificial isolation openings 15A and 15B. The sacrificial isolation openings 15A and 15B may be initial openings for cell isolation and may include large openings 15A and small openings 15B. The size of the large openings 15A may be greater than the size of the small openings 15B. From the perspective of a top view, the large openings 15A and the small openings 15B may have a rectangular shape. According to another embodiment of the present invention, the large openings 15A and the small openings 15B may have a circular shape or an oval shape. According to another embodiment of the present invention, the sacrificial isolation openings 15A and 15B may be referred to as sacrificial isolation trenches. The large openings 15A and the small openings 15B may extend vertically in the first direction D1. The large openings 15A and the small openings 15B may be alternately arranged in the second direction D2. A plurality of large openings 15A may be disposed in the third direction D3. A plurality of small openings 15B may be disposed in the third direction D3. The large openings 15A and the small openings 15B may penetrate the stack body SB in the first direction D1.

After the sacrificial isolation openings 15A and 15B are formed, portions of the lower structure 11 exposed below the sacrificial isolation openings 15A and 15B may be etched. As a result, the bottom surfaces of the sacrificial isolation openings 15A and 15B may extend into the lower structure 11. The bottom surface of the sacrificial isolation openings 15A and 15B may include a U-shaped profile. The fourth layers 14 may have a mesh-shaped pattern due to the sacrificial isolation openings 15A and 15B.

The bottom surface of the sacrificial isolation openings 15A and 15B may be disposed at the first level H1.

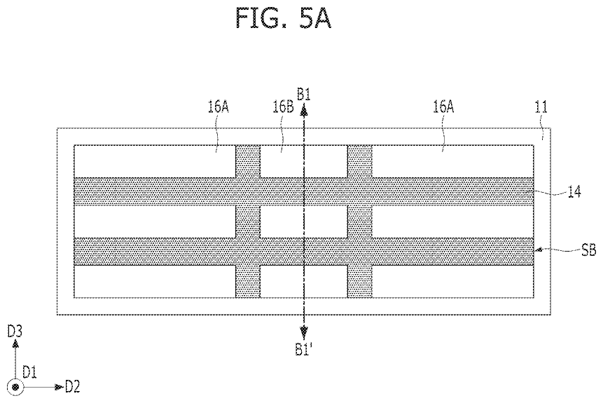

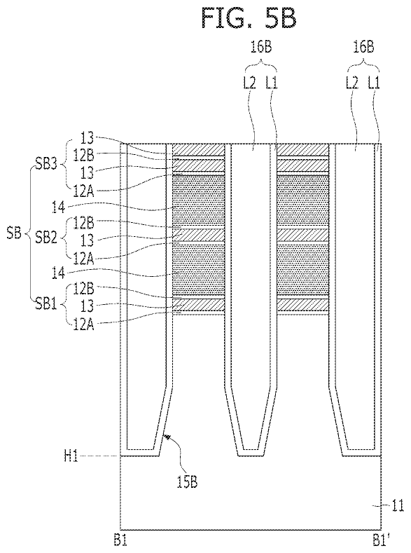

FIG. 5A is a plan view of the fourth layer 14 level illustrating a method of forming the sacrificial isolation layers 16A and 16B, and FIG. 5B is a cross-sectional view taken along a line B1-B1′ shown in FIG. 5A.

Referring to FIGS. 5A and 5B, sacrificial isolation layers 16A and 16B may be formed to fill the sacrificial isolation openings 15A and 15B. The sacrificial isolation layers 16A and 16B may include first sacrificial isolation layers 16A and second sacrificial isolation layers 16B. The first sacrificial isolation layers 16A may fill the large openings 15A, and the second sacrificial isolation layers 16B may fill the small openings 15B.

The first sacrificial isolation layers 16A and the second sacrificial isolation layers 16B may include the same material. The first sacrificial isolation layers 16A and the second sacrificial isolation layers 16B may be formed of a dielectric material. Forming the first sacrificial isolation layers 16A and the second sacrificial isolation layers 16B may include forming sacrificial isolation materials over the stack body SB to fill the sacrificial isolation openings 15A and 15B and planarizing the sacrificial isolation materials to expose the uppermost layer of the stack body SB. The first sacrificial isolation layers 16A and the second sacrificial isolation layers 16B may have different sizes or different volumes. For example, the size (or volume) of the first sacrificial isolation layers 16A may be greater than that of the second sacrificial isolation layers 16B.

The first sacrificial isolation layers 16A and the second sacrificial isolation layers 16B may extend vertically in the first direction D1. The first sacrificial isolation layers 16A and the second sacrificial isolation layers 16B may be alternately arranged in the second direction D2. A plurality of first sacrificial isolation layers 16A may be disposed in the third direction D3. A plurality of second sacrificial isolation layers 16B may be disposed in the third direction D3. The first sacrificial isolation layers 16A and the second sacrificial isolation layers 16B may penetrate the stack body SB in the first direction D1.

The first sacrificial isolation layers 16A and the second sacrificial isolation layers 16B may include the same material. The first sacrificial isolation layers 16A and the second sacrificial isolation layers 16B may be formed of a dielectric material. For example, the first sacrificial isolation layers 16A and the second sacrificial isolation layers 16B may include silicon oxide, silicon nitride, silicon carbon oxide, silicon carbon nitride, or a combination thereof.

The first sacrificial isolation layers 16A and the second sacrificial isolation layers 16B may have different sizes or different volumes. For example, the size (or volume) of the first sacrificial isolation layers 16A may be greater than the second sacrificial isolation layers 16B.

Each of the first and second sacrificial isolation layers 16A and 16B may include a stack of a sacrificial liner layer L1 and a sacrificial gap-fill layer L2. The sacrificial liner layer L1 may include silicon nitride, and the sacrificial gap-fill layer L2 may include silicon oxide.

Forming the first sacrificial isolation layers 16A and the second sacrificial isolation layers 16B may include sequentially forming sacrificial liner layers L1 and sacrificial gap-fill layers L2 over the stack body SB to fill the sacrificial isolation openings 15A and 15B and planarizing the sacrificial liner layers L1 and the sacrificial gap-fill layers L2 to expose the uppermost layer of the stack body SB.

The bottom surfaces of the first and second sacrificial isolation layers 16A and 16B may be disposed at the first level H1.

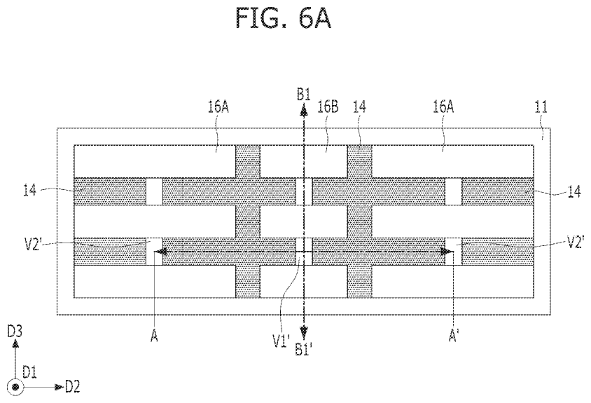

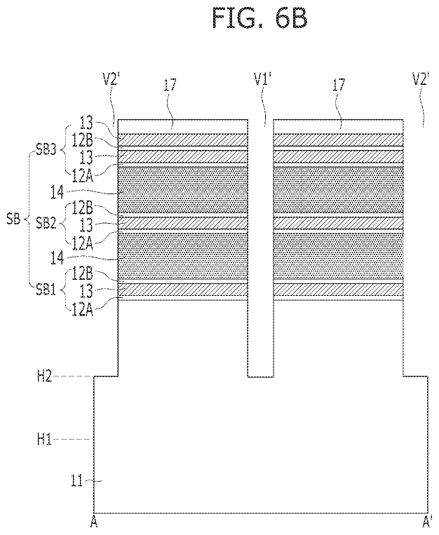

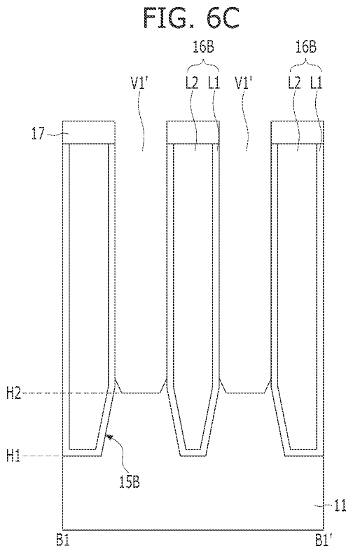

FIG. 6A is a plan view at the level of the fourth layer 14 illustrating a method of forming the sacrificial vertical openings V1′ and V2′, and FIG. 6B is a cross-sectional view taken along a line A-A′ shown in FIG. 6A. FIG. 6C is a cross-sectional view taken along a line B1-B1′ shown in FIG. 6A.

Referring to FIGS. 6A to 6C, a hard mask layer pattern 17 may be formed over the stack body SB, the first sacrificial isolation layers 16A, and the second sacrificial isolation layers 16B. The hard mask layer pattern 17 may include silicon nitride. The hard mask layer pattern 17 may be formed by an etching process using a mask layer (not shown). The hard mask layer pattern 17 may have a plurality of hole-type openings defined.

Subsequently, portions of the stack body SB may be etched using the hard mask layer pattern 17 as an etch barrier. As a result, a plurality of sacrificial vertical openings V1′ and V2′ may be formed in the stack body SB. The sacrificial vertical openings V1′ and V2′ may include first sacrificial vertical openings V1′ and second sacrificial vertical openings V2′. The first sacrificial vertical openings V1′ and the second sacrificial vertical openings V2′ may be hole-type openings. The first sacrificial vertical openings V1′ and the second sacrificial vertical openings V2′ may extend vertically in the first direction D1. The first sacrificial vertical openings V1′ and the second sacrificial vertical openings V2′ may be formed by etching the stack body SB between the first sacrificial isolation layers 16A and the second sacrificial isolation layers 16B. The first sacrificial vertical openings V1′ may be formed by etching the stack body SB between the second sacrificial isolation layers 16B. The second sacrificial vertical openings V2′ may be formed by etching the stack body SB between the first sacrificial isolation layers 16A. The first sacrificial vertical openings V1′ may be disposed between the second sacrificial isolation layers 16B in the third direction D3. The second sacrificial vertical openings V2′ may be disposed between the first sacrificial isolation layers 16A in the third direction D3. From the perspective of a top view, the cross-sections of the first and second sacrificial vertical openings V1′ and V2′ may have a square shape, a circular shape or an oval shape.

The bottom surfaces of the first and second sacrificial vertical openings V1′ and V2′ may be disposed at a second level H2. The second level H2 of the first and second sacrificial vertical openings V1′ and V2′ may be higher than the first level H1 of the first and second sacrificial isolation openings 15A and 15B. The second level H2 of the first and second sacrificial vertical openings V1′ and V2′ may be higher than the first level H1 of the first and second sacrificial isolation layers 16A and 16B.

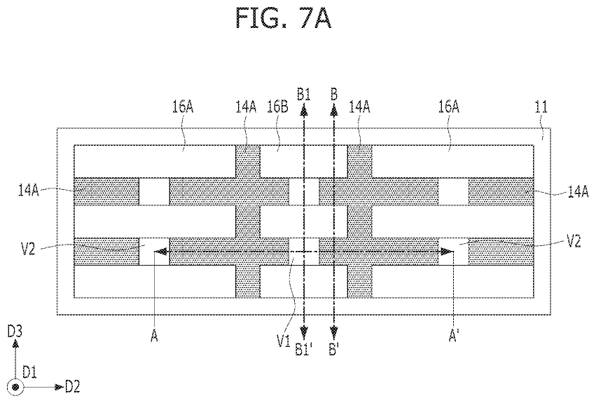

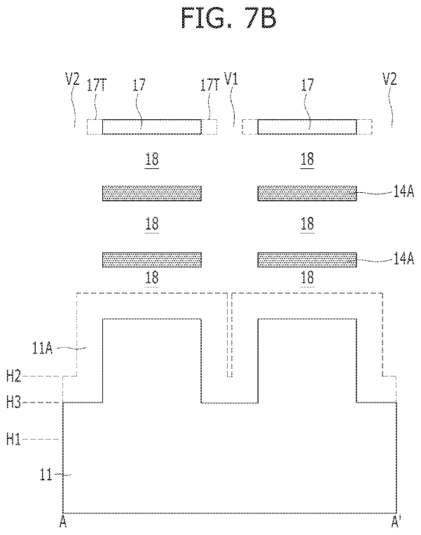

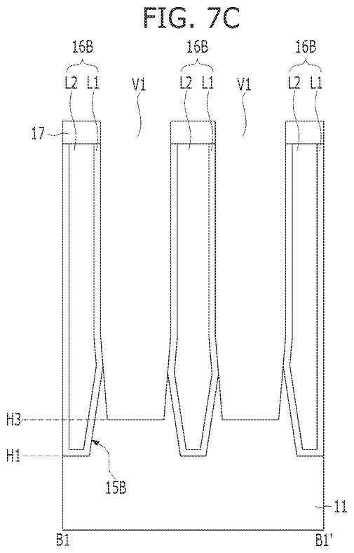

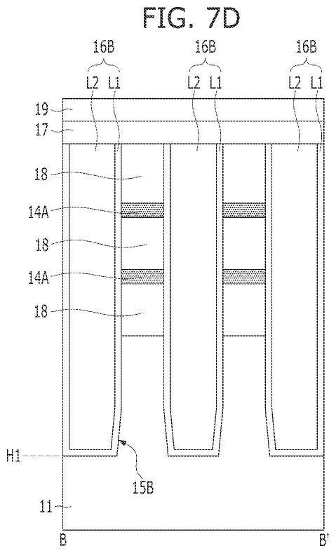

FIG. 7A is a plan view illustrating a method of forming a preliminary horizontal layer 14A, and FIG. 7B is a cross-sectional view taken along a line A-A′ shown in FIG. 7A, and FIG. 7C is a cross-sectional view taken along a line B1-B1′ shown in FIG. 7A. FIG. 7D is a cross-sectional view taken along a line B-B′ shown in FIG. 7A.

Referring to FIGS. 7A to 7D, a portion of the hard mask layer pattern 17 may be trimmed (refer to a reference numeral ‘17T’).

Subsequently, the first and third layers 12A and 12B may be selectively removed through the first and second sacrificial vertical openings V1′ and V2′. In order to selectively remove the first layers 12A and the third layers 12B, the difference in etch selectivity between the second and fourth layers 13 and 14 and the first and third layers 12A and 12B may be used. The first layers 12A and the third layers 12B may be removed using a wet etching process or a dry etching process. For example, when the first layers 12A and the third layers 12B include a silicon germanium layer and the second layers 13 and the fourth layers 14 include a monocrystalline silicon layer, the silicon germanium layers may be etched using an etchant or an etching gas having a selectivity with respect to the monocrystalline silicon layers.

Subsequently, the second layers 13 and the fourth layers 14 may be recessed. In order to recess the second layers 13 and the fourth layers 14, a wet etching process or a dry etching process may be used. According to this embodiment of the present invention, the fourth layers 14 may be partially etched while the second layers 13 are removed. As a result, the second layers 13 may be removed, and the fourth layers 14 may become thin as indicated by a reference numeral ‘14A’. The recess process for forming the thin fourth layer 14A, that is, the preliminary horizontal layers 14A, may be referred to as a thinning process or a trimming process of the fourth layers 14. To form the preliminary horizontal layers 14A, the top surfaces, bottom surfaces and side surfaces of the fourth layers 14 may be recessed. The preliminary horizontal layers 14A may be referred to as thin-body active layers. The preliminary horizontal layers 14A may include a monocrystalline silicon layer. The recess process for forming the preliminary horizontal layers 14A may use, for example, HSC1 (Hot SC-1). HSC1 may include a mixed solution in which ammonium hydroxide (NH₄OH), hydrogen peroxide (H₂O₂) and water (H₂O) are mixed at a ratio of approximately 1:4:20. The second layers 13 and the fourth layers 14 may be selectively etched using the HSC1.

The preliminary horizontal layers 14A may be formed by the above-described recess process for recessing the fourth layers 14, and horizontal recesses 18 may be formed between the preliminary horizontal layers 14A. Each of the upper and bottom surfaces of the preliminary horizontal layers 14A may include a flat surface.

From the perspective of a top view, the preliminary horizontal layers 14A may have a cross shape. The side surfaces of the preliminary horizontal layers 14A may have a bent shape or a rounded shape.

After the preliminary horizontal layers 14A are formed, the first and second sacrificial vertical openings may be expanded as indicated by reference symbols ‘V1’ and ‘V2’. The preliminary horizontal layers 14A may be spaced apart from each other by the first and second sacrificial vertical openings V1 and V2 in the second direction D2. The preliminary horizontal layers 14A may have a shape in which a plurality of cross shapes are merged in the third direction D3.

While the preliminary horizontal layers 14A are formed, the surface of the lower structure 11 may be recessed to a certain depth (see reference numeral ‘11A’). As a result, the depth of the first and second sacrificial vertical openings V1′ and V2′ may be increased. The bottom surfaces of the first and second sacrificial vertical openings V1′ and V2′ may be lowered from the second level H₂ to a third level H₃. The bottom surfaces of the expanded first and second sacrificial vertical openings V1 and V2 may be disposed at the third level H₃. The third level H₃ of the first and second sacrificial vertical openings V1 and V2 may be higher than the first level H₁ of the first and second sacrificial isolation openings 15A and 15B. The third level H₃ of the first and second sacrificial vertical openings V1 and V2 may be higher than the first level H₁ of the first and second sacrificial isolation layers 16A and 16B. According to another embodiment of the present invention, the third level H₃ of the first and second sacrificial vertical openings V1 and V2 may be the same as the first level H₁.

The first sacrificial vertical openings V1 and the second sacrificial vertical openings V2 may be alternately disposed between the preliminary horizontal layers 14A in the second direction D2. The first sacrificial vertical openings V1 may be disposed in the third direction D3 between the second sacrificial isolation layers 16B, and the second sacrificial vertical openings V2 may be disposed in the third direction D3 between the first sacrificial isolation layers 16A.

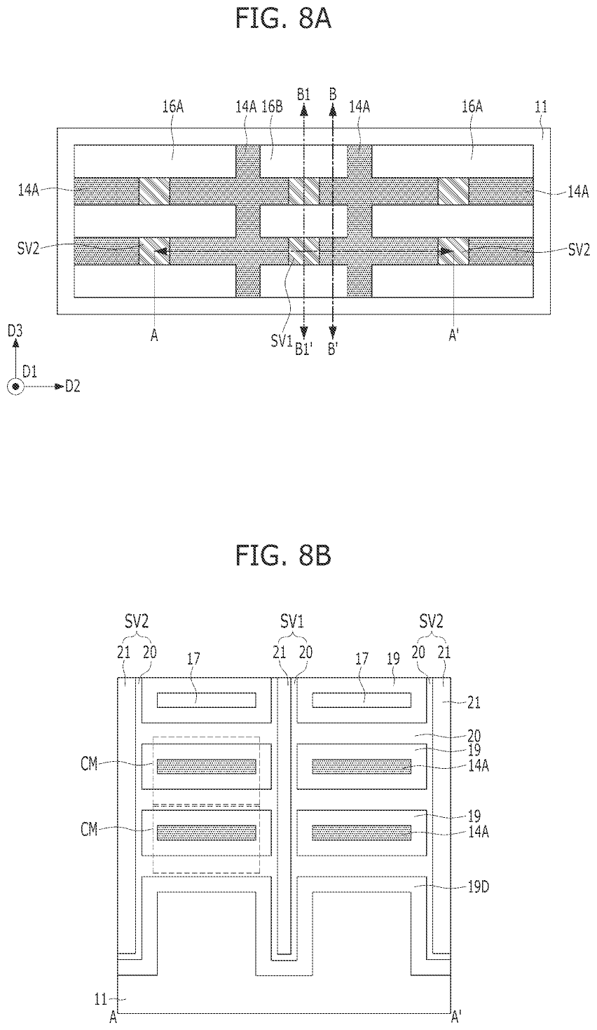

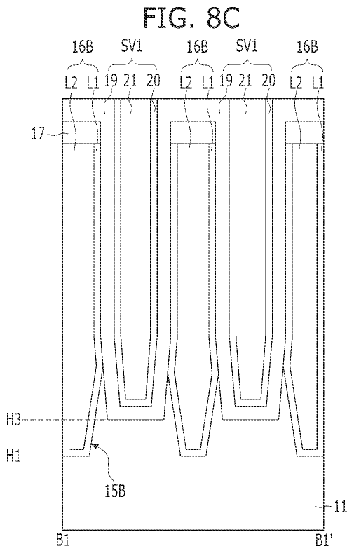

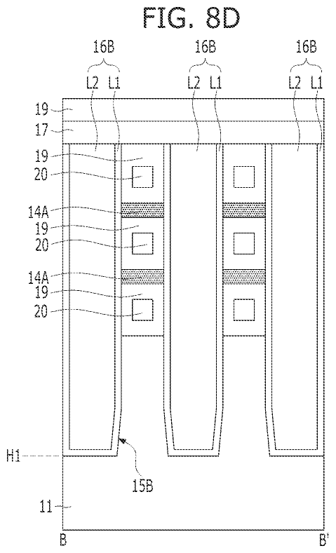

FIG. 8A is a plan view illustrating a method of forming a first dielectric layer 19 and a second dielectric layer 20, and FIG. 8B is a cross-sectional view taken along a line A-A′ shown in FIG. 8A. FIG. 8C is a cross-sectional view taken along a line B1-B1′ shown in FIG. 8A. FIG. 8D is a cross-sectional view taken along a line B-B′ shown in FIG. 8A.

Referring to FIGS. 8A to 8D, the first dielectric layers 19 covering the preliminary horizontal layers 14A may be formed. The first dielectric layers 19 may include silicon nitride. The first dielectric layers 19 may fully cover the top surface, bottom surface, and side surfaces of the preliminary horizontal layers 14A.

While the first dielectric layers 19 are formed, a dummy dielectric layer 19D may be formed on the surface of the lower structure 11. Some of the first dielectric layers 19 may fully cover the top surface, bottom surface, and side surfaces of the hard mask layer pattern 17.

Subsequently, the second dielectric layer 20 may be formed over the first dielectric layers 19. The second dielectric layer 20 may fill between the vertically neighboring first dielectric layers 19. The second dielectric layer 20 may include silicon oxide. Portions of the second dielectric layer 20 may be conformally formed on the surfaces of the first and second sacrificial vertical openings V1 and V2. The horizontal recesses (18 in FIGS. 7B and 7C) may be filled with the first dielectric layer 19 and the second dielectric layer 20.

Subsequently, a sacrificial pillar 21 may be formed over the second dielectric layer 20 which is disposed in the first and second sacrificial vertical openings V1 and V2. The sacrificial pillar 21 may be a sacrificial material and may include amorphous carbon. According to another embodiment of the present invention, a pillar capping layer may be further formed over the sacrificial pillar 21. The pillar capping layer may include a metal-based material. The pillar capping layer may include titanium nitride. Forming the sacrificial pillar 21 may include depositing a sacrificial material and planarizing the sacrificial material. The planarization process for forming the sacrificial pillar 21 may be performed until the uppermost-level first dielectric layer 19 is exposed. Subsequently, the uppermost-level second dielectric layers 20 may also be planarized until the uppermost-level first dielectric layer 19 is exposed. The sacrificial pillar 21 may not be formed between the vertically stacked first dielectric layers 19.

The second dielectric layer 20 and the sacrificial pillar 21 may form first and second sacrificial pillar structures SV1 and SV2 that fill the first and second sacrificial vertical openings V1 and V2. The first sacrificial pillar structure SV1 may fill the first sacrificial vertical openings V1, and the second sacrificial pillar structure SV2 may fill the second sacrificial vertical openings V2. According to another embodiment of the present invention, the first and second sacrificial pillar structures SV1 and SV2 may include a dielectric material, a carbon-containing material, a metal-based material, or a combination thereof. According to another embodiment of the present invention, the first and second sacrificial pillar structures SV1 and SV2 may include silicon oxide, silicon nitride, titanium nitride, amorphous carbon, or a combination thereof. From the perspective of a top view, the first sacrificial pillar structure SV1 and the second sacrificial pillar structure SV2 may be hole-type sacrificial pillars. According to another embodiment of the present invention, portions of the first dielectric layer 19 may be conformally formed on the surfaces of the first and second sacrificial vertical openings V1 and V2. Therefore, the first and second sacrificial pillar structures SV1 and SV2 may further include portions of the first dielectric layer 19.

The bottom surfaces of the first and second sacrificial pillar structures SV1 and SV2 may be disposed at the third level H₃.

Referring back to FIG. 8D, the first dielectric layers 19 may be formed between the preliminary horizontal layers 14A, and second dielectric layers 20 may be formed inside the first dielectric layers 19. The first dielectric layers 19 may surround the second dielectric layers 20. The first dielectric layers 19 may include a first surrounding portion and a second surrounding portion, wherein the first surrounding portion may surround the preliminary horizontal layers 14A in a A-A′ direction, and the second surrounding portion may surround the second dielectric layers 20 in a B-B′ direction and a C-C′ direction.

As described above, a cell mold structure may be formed by forming the preliminary horizontal layers 14A, the first dielectric layers 19, and the second dielectric layers 20. The cell mold structure may include a plurality of cell molds CM. Each of the cell molds CM may include a plurality of mold layers. The mold layers may refer to the preliminary horizontal layers 14A, the first dielectric layers 19 and the second dielectric layers 20. Each cell mold CM may include an ONSN (Oxide-Nitride-Silicon-Nitride) stack. Here, the ONSN stack may refer to a structure in which a silicon oxide, a first silicon nitride, a monocrystalline silicon layer, and a second silicon nitride are sequentially stacked. The silicon oxide may correspond to the second dielectric layers 20, and the first and second silicon nitride may correspond to the first dielectric layers 19. The monocrystalline silicon layer may correspond to the preliminary horizontal layers 14A. The cell mold structure including the cell molds CM may be referred to as a vertical stack. From the perspective of another view, the cell mold structure may include an ONSNO (Oxide-Nitride-Silicon-Nitride-Oxide) stack. Here, the ONSNO stack may refer to a structure in which a first silicon oxide, a first silicon nitride, a monocrystalline silicon layer, a second silicon nitride, and a second silicon oxide are sequentially stacked.

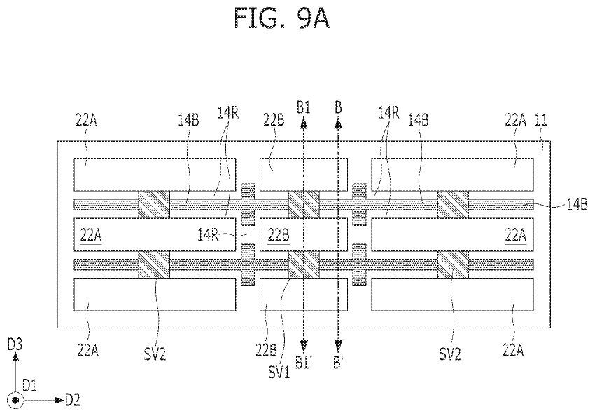

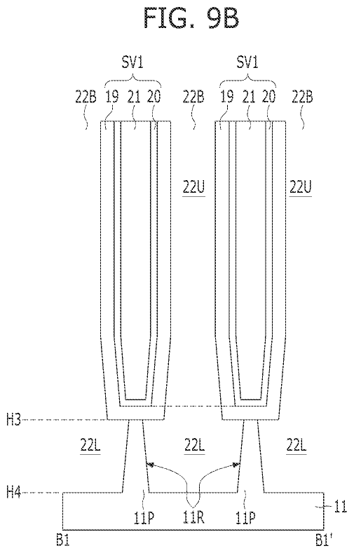

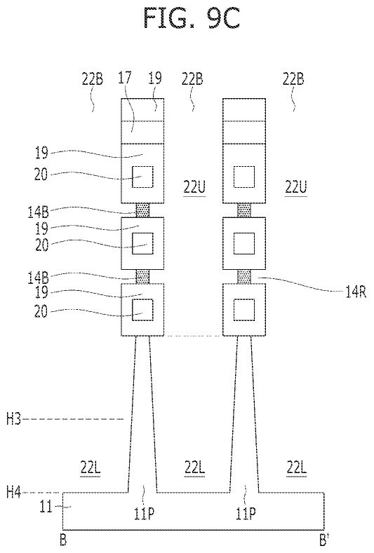

As described above, the sub-stacks of the stack body SB may be replaced with cell molds CM through a series of processes according to FIGS. 4A to 8D. The first layers 12A, the second layers 13, and the third layers 12B may be replaced with the first dielectric layers 19 and the second dielectric layers 20. The fourth layers 14 may become the preliminary horizontal layer 14A through a recess process. The first dielectric layers 19 may be referred to as a trimming target layer. FIG. 9A is a plan view illustrating a method of forming the cell isolation openings 22A and 22B and the horizontal layers 14B, and FIG. 9B is a cross-sectional view taken along a line B1-B1′ shown in FIG. 9A. FIG. 9C is a cross-sectional view taken along a line B-B′ shown in FIG. 9A.

Referring to FIGS. 9A to 9C, the first and sacrificial isolation layers 16A and 16B may be removed to form the cell isolation openings 22A and 22B. The cell isolation openings 22A and 22B may include first cell isolation openings 22A and second cell isolation openings 22B. The first cell isolation openings 22A may be formed by removing the first sacrificial isolation layers 16A. The second cell isolation openings 22B may be formed by removing the second sacrificial isolation layers 16B. While the first and second sacrificial isolation layers 16A and 16B are removed, the first and second sacrificial pillar structures SV1 and SV2 may be covered by a mask layer (not shown). The first and second cell isolation openings 22A and 22B may expose the side surfaces of the preliminary horizontal layers 14A and the first dielectric layers 19 in the B-B′ direction.

Subsequently, the side surfaces of the preliminary horizontal layers 14A of the cell molds CM may be trimmed in the second direction D2 and the third direction D3 through the first and second cell isolation openings 22A and 22B. As a result, the trimmed horizontal layers 14B may be formed. The horizontal layer level gaps 14R may be formed on the side surfaces of the horizontal layers 14B. The horizontal layer level gap 14R and the horizontal layers 14B may be disposed between the first dielectric layers 19. The horizontal layers 14B may be referred to as ‘trimmed horizontal layer patterns’.

While the horizontal layers 14B are formed, the surface of the lower structure 11, for example, the bottom surfaces of the first and second cell isolation openings 22A and 22B, may be expanded (see a reference numeral ‘11R’). As a result, the bottom surfaces of the first and second cell isolation openings 22A and 22B may be disposed at the fourth level H₄. The fourth level H₄ of the first and second cell isolation openings 22A and 22B may be lower than the third level H₃ of the first and second sacrificial vertical openings V1 and V2 and the first and second sacrificial pillar structures SV1 and SV2. The fourth level H₄ of the first and second cell isolation openings 22A and 22B may be lower than the first level H₁ of the first and second sacrificial isolation openings 15A and 15B and the first and second sacrificial isolation layers 16A and 16B. In this way, the bottom surfaces of the first and second cell isolation openings 22A and 22B may be lower than the bottom surfaces of the first and second sacrificial vertical openings V1 and V2 and the bottom surfaces of the first and second sacrificial pillar structures SV1 and SV2.

While the horizontal layers 14B are formed, supporters 11P may be formed below the first and second sacrificial pillar structures SV1 and SV2. The supporters 11P may be disposed between the first cell isolation openings 22A and the second cell isolation openings 22B. The supporters 11P may be formed by recessing the surface of the lower structure 11. When the lower structure 11 includes monocrystalline silicon, the supporters 11P may also include monocrystalline silicon.

Each of the first and second cell isolation openings 22A and 22B may have a lower region 22L disposed between the supporters 11P and an upper region 22U disposed between the first sacrificial pillar structures SV1 and the second sacrificial pillar structures SV2. The horizontal width of the lower region 22L may be greater than the horizontal width of the upper region 22U. As described above, due to the lower region 22L and the upper region 22U having different horizontal widths, the cell isolation openings 22A and 22B may become bulb-shaped openings.

The horizontal layers 14B may be disposed between the first sacrificial pillar structure SV1 and the second sacrificial pillar structure SV2 in the second direction D2. From the perspective of a top view, the horizontal layers 14B may have a cross shape. The horizontal layers 14B may have a cross shape whose size is smaller than the size of the preliminary horizontal layers 14A. The preliminary horizontal layers 14A may have a shape in which a plurality of cross shapes are merged, and the horizontal layers 14B may have a shape in which the cross shapes are individually separated in the third direction D3. The horizontal layer level gap 14R may be formed between the horizontal layers 14B that are arranged in the third direction D3. The first and second sacrificial pillar structures SV1 and SV2 may be disposed between the horizontal layers 14B in the second direction D2.

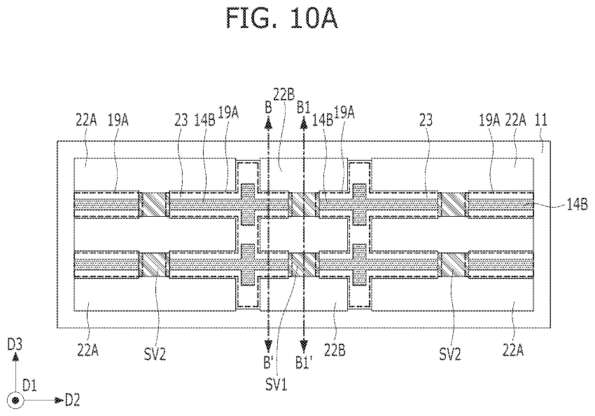

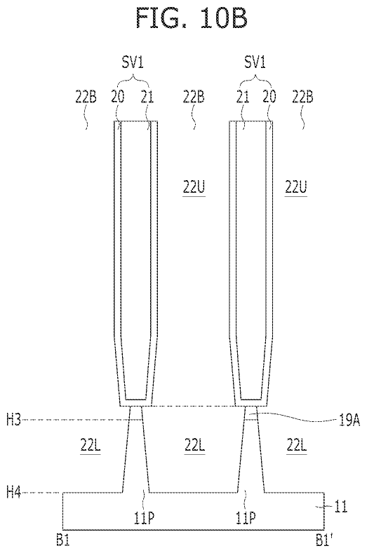

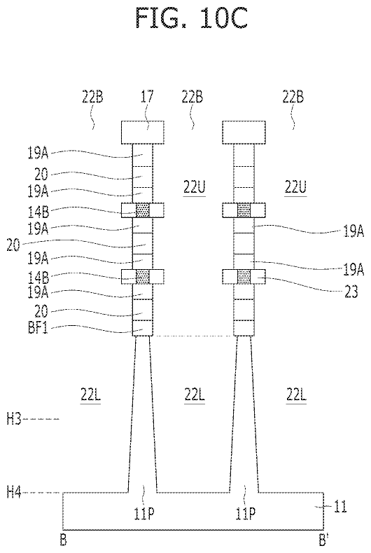

FIG. 10A is a plan view illustrating a method of forming horizontal layer level spacers 23 and first dielectric layers 19A, and FIG. 10B is a cross-sectional view taken along a line B1-B1′ shown in FIG. 10A. FIG. 10C is a cross-sectional view taken along a line B-B′ shown in FIG. 10A.

Referring to FIGS. 10A to 10C, horizontal layer level spacers 23 may be formed on the side surfaces of the horizontal layers 14B. Forming the horizontal layer level spacers 23 may include forming a spacer material on the side surfaces of the horizontal layers 14B and etching the spacer material. The horizontal layer level spacers 23 may comprise a dielectric material, for example silicon oxide. The horizontal layer level spacers 23 may fill the horizontal layer level gaps 14R. The horizontal layers 14B arranged in the third direction D3 may be isolated from each other by the horizontal layer level spacers 23.

Subsequently, a portion of the first dielectric layers 19 may be trimmed horizontally through the first and second cell isolation openings 22A and 22B. After the trimming process, the first dielectric layers 19 may remain as indicated by a reference numeral ‘19A’. Accordingly, from the perspective of the B-B′ direction, a pair of first dielectric layers 19A may be disposed between the horizontal layers 14B, and one second dielectric layer 20 may be disposed between the first dielectric layers 19A of the pair.

According to FIGS. 9A to 10C, the width of the first dielectric layers 19A in the third direction D3 between the first cell isolation openings 22A and the second cell isolation openings 22B may be greater than the width of the horizontal layers 14B. The trimming depth of the first dielectric layers 19 in the third direction D3 may be smaller than the trimming depth of the preliminary horizontal layers 14A.

A pair of first dielectric layers 19A may vertically overlap with one horizontal layer 14B. The trimmed first dielectric layers 19A may be referred to as trimmed first dielectric layers.

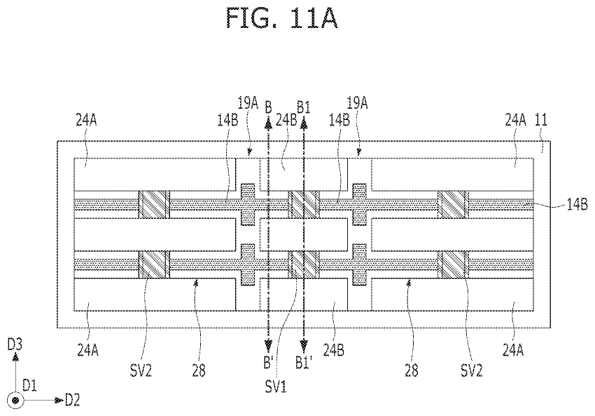

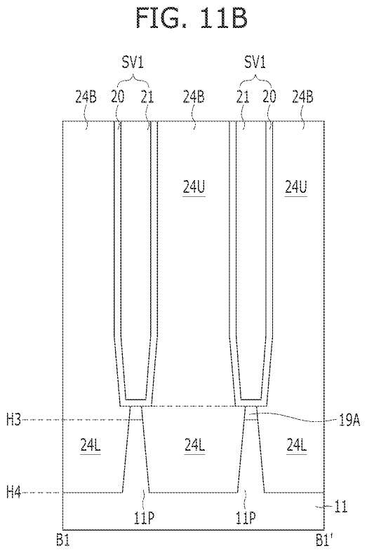

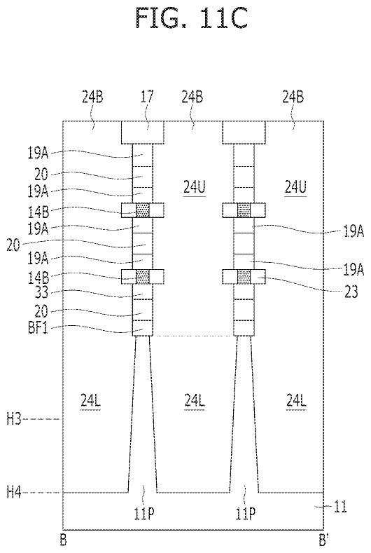

FIG. 11A is a plan view illustrating a method of forming the cell isolation layers 24A and 24B, and FIG. 11B is a cross-sectional view taken along a line B1-B1′ shown in FIG. 11A. FIG. 11C is a cross-sectional view taken along a line B-B′ shown in FIG. 11A. FIG. 11A may be a plan view at the level of the first dielectric layer 19A illustrating a method of forming the cell isolation layers 24A and 24B. Referring to FIGS. 11A to 11C, cell isolation layers 24A and 24B may be formed to fill the first and second cell isolation openings 22A and 22B. The cell isolation layers 24A and 24B may include first cell isolation layers 24A and second cell isolation layers 24B. The first cell isolation layers 24A and the second cell isolation layers 24B may include the same material. The first cell isolation layers 24A and the second cell isolation layers 24B may be formed of a dielectric material. For example, the first cell isolation layers 24A and the second cell isolation layers 24B may include silicon oxide, silicon nitride, silicon carbon oxide, silicon carbon nitride, or a combination thereof. From the perspective of a top view, the outermost material of the first cell isolation layers 24A and the second cell isolation layers 24B may include silicon oxide.

Forming the first cell isolation layers 24A and the second cell isolation layers 24B may include forming a cell isolation material that fills the first and second cell isolation openings 22A and 22B and planarizing the cell isolation material and the uppermost first dielectric layer 19A to expose the surface of the hard mask layer pattern 17. The first cell isolation layers 24A and the second cell isolation layers 24B may have different sizes or different volumes. The second sacrificial pillar structure SV2 may be disposed between the first cell isolation layers 24A in the third direction D3, and the first sacrificial pillar structure SV1 may be disposed between the second cell isolation layers 24B in the third direction D3. The first and second cell isolation layers 24A and 24B may extend vertically in the first direction D1.

The first and second cell isolation layers 24A and 24B may correspond to the cell isolation layers ISOA and ISOB illustrated in FIGS. 2 to 3D. Each of the first and second cell isolation layers 24A and 24B may include a stack of a cell isolation liner layer ISOL and a cell isolation gap-fill layer ISOG, which are illustrated in FIGS. 3C and 3D. The cell isolation liner layers ISOL may include silicon oxide, and the cell isolation gap-fill layers ISOG may include silicon carbon oxide. According to another embodiment of the present invention, the first and second cell isolation layers 24A and 24B may include an embedded air gap, and the embedded air gap may be provided when the cell isolation gap-fill layers ISOG are formed.

The first and second cell isolation layers 24A and 24B and the first dielectric layers 19A may directly contact each other. A horizontal layer level spacer 23 may be disposed between the horizontal layers 14B and the first and second cell isolation layers 24A and 24B.

The first and second cell isolation layers 24A and 24B may be disposed at the fourth level H₄, and the first and second sacrificial pillar structures SV1 and SV2 may be disposed at the third level H₃. The fourth level H₄ may be greater than the third level H₃. According to the above description, the fourth level H₄ may be expanded from the first level H₁, and the third level H₃ may be expanded from the second level H₂. The fourth level H₄ may be lower than the first level H₁, the second level H₂, and the third level H₃.

Each of the first and second cell isolation layers 24A and 24B may include a lower isolation area 24L disposed between the supporters 11P and an upper isolation area 24U disposed between the first and second sacrificial pillar structures SV1 and SV2. The horizontal width of the lower isolation area 24L may be greater than the horizontal width of the upper isolation area 24U. As described above, the cell isolation layers 24A and 24B may be bulb-shaped isolation layers due to the lower isolation area 24L and the upper isolation area 24U having different horizontal widths.

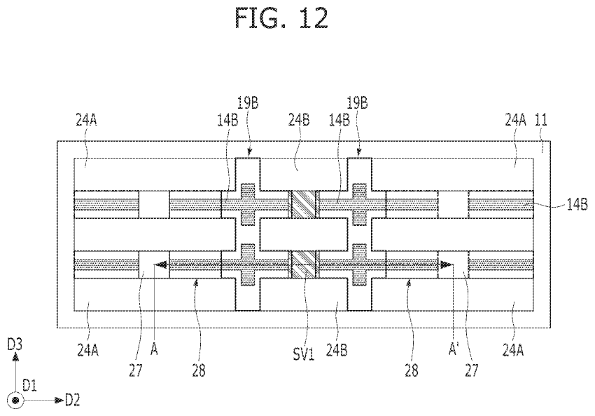

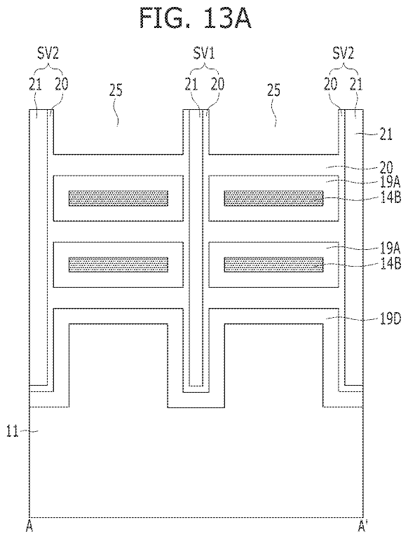

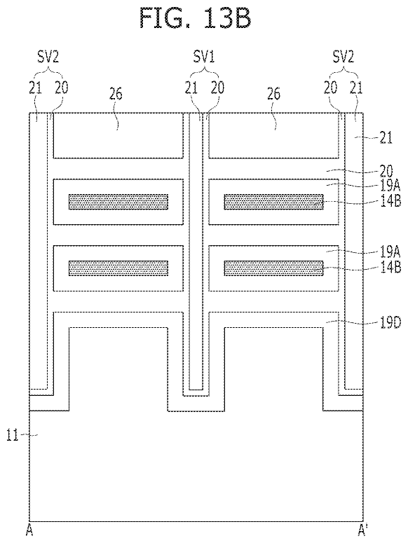

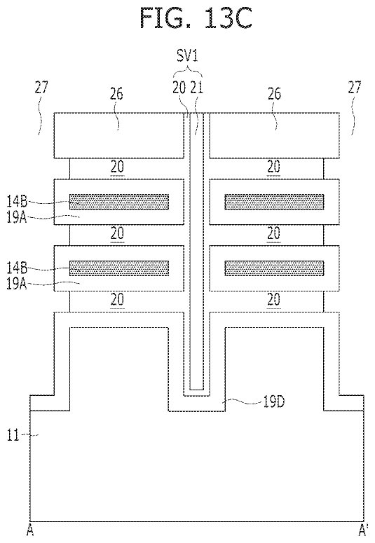

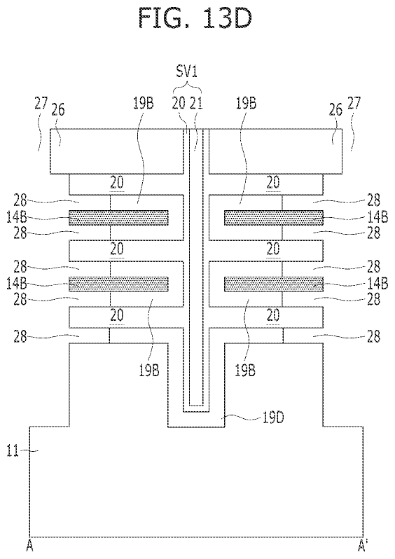

FIG. 12 is a plan view illustrating a method of forming the first dielectric layer patterns 19B, and FIGS. 13A to 13D are first dielectric layer patterns 19B taken along a line A-A′ shown in FIG. 12.

Referring to FIG. 13A, the hard mask layer 17 and the first dielectric layer 19A at the uppermost level may be removed to form hard mask layer level recesses 25.

Referring to FIG. 13B, a top dielectric layer 26 that fills the hard mask layer level recesses 25 may be formed. The top dielectric layer 26 may include silicon oxide.

Referring to FIG. 13C, initial vertical openings 27 may be formed by removing the first sacrificial pillar structures SV1. Subsequently, the second dielectric layers 20 may be horizontally recessed, and thus the first dielectric layers 19A and the dummy dielectric layer 19D may be exposed.

Referring to FIG. 13D, the dummy dielectric layer 19D and the first dielectric layers 19A may be selectively horizontally recessed. As a result, first dielectric layer patterns 19B and dielectric layer level recesses 28 may be formed. Portions of the horizontal layers 14B may be exposed by the dielectric layer level recesses 28.

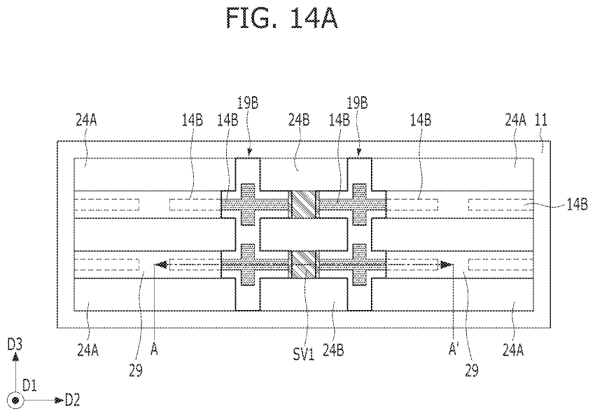

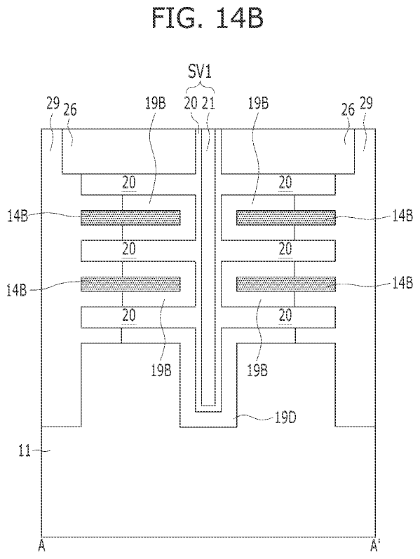

FIG. 14A is a plan view illustrating a method of forming vertical sacrificial structures 29, and FIG. 14B is a cross-sectional view taken along a line A-A′ shown in FIG. 14A.

Referring to FIGS. 14A and 14B, the vertical sacrificial structures 29 may be formed to fill the dielectric layer level recesses 28 and the initial vertical openings 27. The vertical sacrificial structures 29 may include a sacrificial material. The vertical sacrificial structures 29 may include silicon oxide, silicon nitride, titanium nitride, amorphous carbon, or a combination thereof.

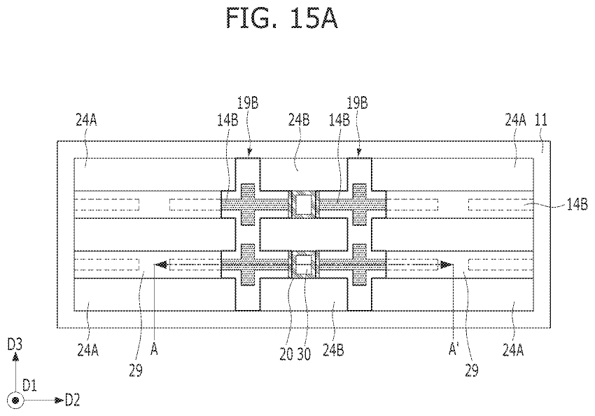

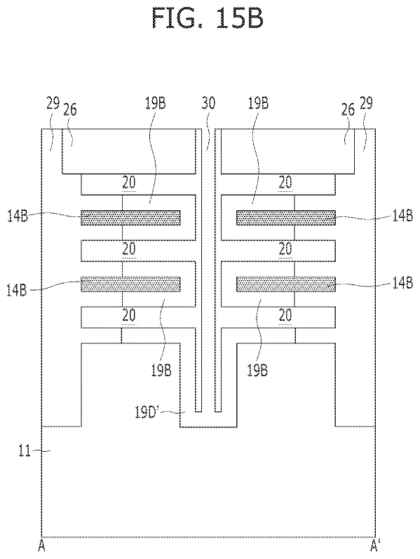

FIG. 15A is a plan view illustrating a method of forming a vertical level path 30, and FIG. 15B is a cross-sectional view taken along a line A-A′ shown in FIG. 15A.

Referring to FIGS. 15A and 15B, in order to form the vertical level path 30, the sacrificial pillar 21 of the first sacrificial pillar structure SV1 may be removed.

Subsequently, the dummy dielectric layer 19D below the vertical level path 30 may be removed to form a lower level gap 19D′.

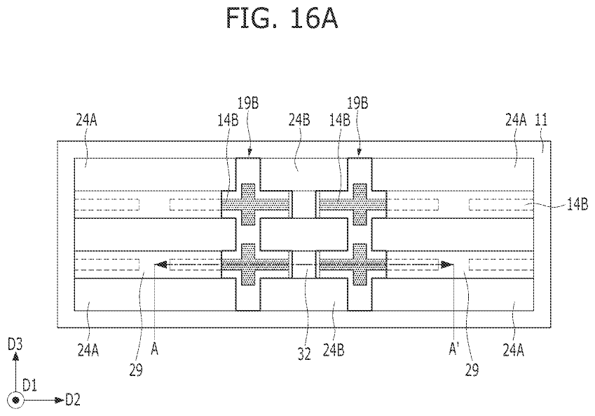

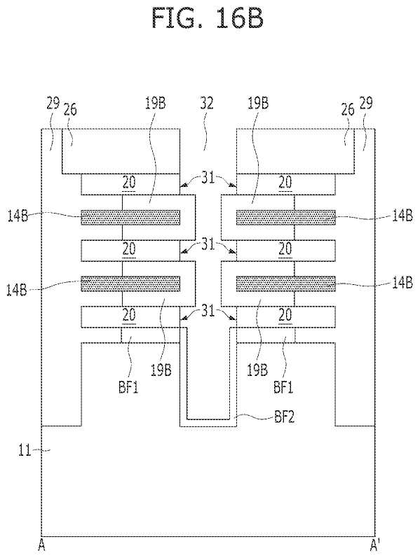

FIG. 16A is a plan view illustrating a method of forming first hole-type vertical openings 32, and FIG. 16B is a cross-sectional view taken along a line A-A′ shown in FIG. 16A.

Referring to FIGS. 16A and 16B, the second dielectric layers 20 may be cut (see 31) through the vertical level path 30 to form the first hole-type vertical openings 32.

Subsequently, a first passivation layer BF1 may be formed to fill the lower level gap 19D′. The first passivation layer BF1 may include silicon oxide. Forming the first passivation layer BF1 may include depositing silicon oxide to fill the lower level gap 19D′ and etching the silicon oxide.

Subsequently, a second passivation layer BF2 may be formed in the lower region of the first hole-type vertical opening 32. For example, the surface of the lower structure 11 may be oxidized to form the second passivation layer BF2.

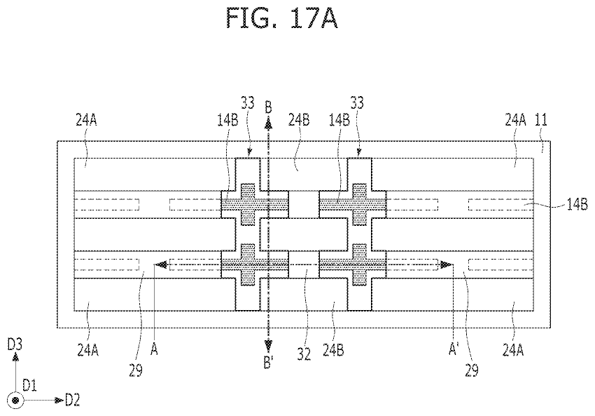

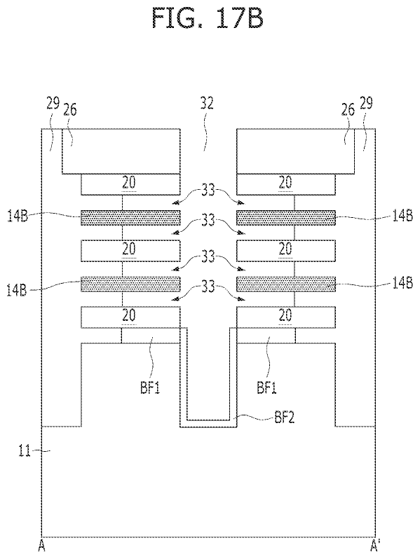

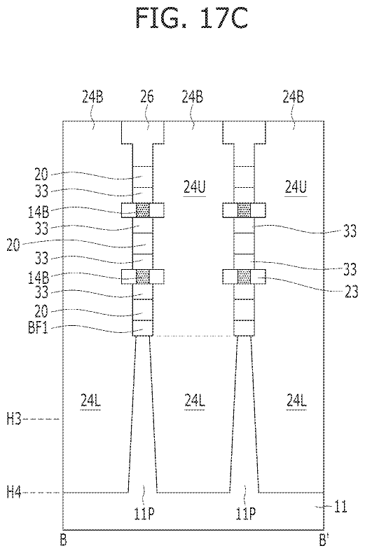

FIG. 17A is a plan view illustrating a method of forming the horizontal level recesses 33, and FIG. 17B is a cross-sectional view taken along a line A-A′ shown in FIG. 17A. FIG. 17C is a cross-sectional view taken along a line B-B′ shown in FIG. 17A.

Referring to FIGS. 17A to 17C, the first dielectric layer patterns 19B may be removed through the first hole-type vertical opening 32 to form horizontal level recesses 33. Portions of the horizontal layers 14B may be exposed by the horizontal level recesses 33. Referring to FIG. 17C, the horizontal level recesses 33 may be disposed between the second dielectric layer 20 and the horizontal layer 14B. Two horizontal level recesses 33 may face each other with one horizontal layer 14B disposed therebetween.

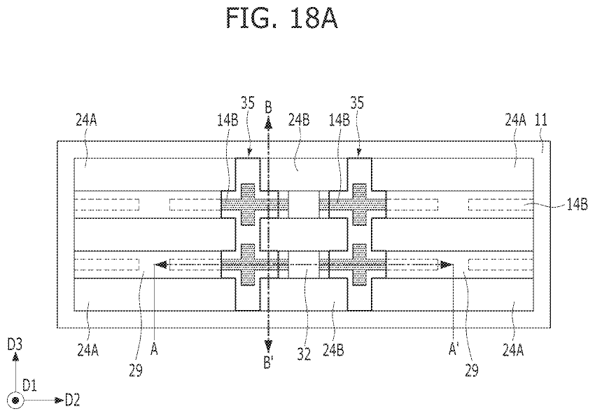

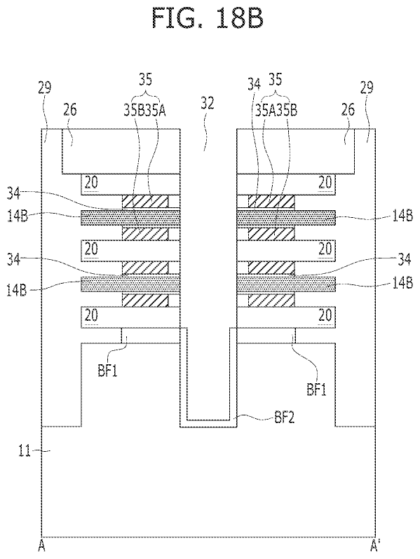

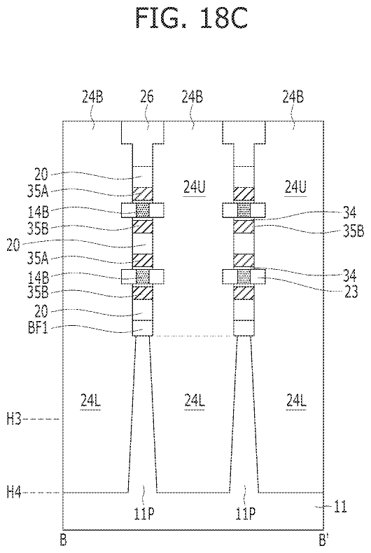

FIG. 18A is a plan view illustrating a method of forming horizontal conductive lines 35, and FIG. 18B is a cross-sectional view taken along a line A-A′ shown in FIG. 18A. FIG. 18C is a cross-sectional view taken along a line B-B′ shown in FIG. 18A.

Referring to FIGS. 18A to 18C, an inter-level dielectric layer 34 may be formed on the exposed portions of the horizontal layers 14B. The inter-level dielectric layer 34 may be referred to as a gate dielectric layer. The inter-level dielectric layer 34 may correspond to the inter-level dielectric layer GD as illustrated in FIGS. 1A to 3B.

The inter-level dielectric layer 34 may be formed by oxidizing the surfaces of the horizontal layers 14B. According to another embodiment of the present invention, the inter-level dielectric layer 34 may be formed by a process which includes depositing silicon oxide. The inter-level dielectric layer 34 may include silicon oxide, silicon nitride, a metal oxide, a metal oxynitride, a metal silicate, a high-k material, a ferroelectric material, an anti-ferroelectric material or a combination thereof. The inter-level dielectric layer 34 may include SiO₂, Si₃N₄, HfO₂, Al₂O₃, ZrO₂, AlON, HfON, HfSiO, HfSiON, or a combination thereof.

Subsequently, a horizontal conductive line 35 that fills the horizontal level recesses 33 may be formed over the inter-level dielectric layer 34. Forming the horizontal conductive line 35 may include depositing a conductive material that fills the horizontal level recesses 33 over the inter-level dielectric layer 34 and etch-backing the conductive material. The horizontal conductive line 35 may include a pair of first and second horizontal conductive lines 35A and 35B that are facing each other with the horizontal layer 14B disposed therebetween. The first and second horizontal conductive lines 35A and 35B may include a metal-based material, a semiconductor material, or a combination thereof. The first and second horizontal conductive lines 35A and 35B may include titanium nitride, tungsten, polysilicon, or a combination thereof. For example, the first and second horizontal conductive lines 35A and 35B may include a TiN/W stack in which titanium nitride and tungsten are sequentially stacked. The first and second horizontal conductive lines 35A and 35B may include an N-type work function material or a P-type work function material. The N-type work function material may have a low work function of approximately 4.5 eV or less, and the P-type work function material may have a high work function of approximately 4.5 eV or more.

The horizontal conductive line 35 may correspond to the second conductive line DWL as illustrated in FIGS. 1A to 1D, and the first and second horizontal conductive lines 35A and 35B may correspond to the upper horizontal line G1 and the lower horizontal line G2. Referring to FIGS. 1A to 1D, each of the first and second horizontal conductive lines 35A and 35B may have a cross shape, and may include a channel overlapping portion WLP and a channel non-overlapping portion NOL.

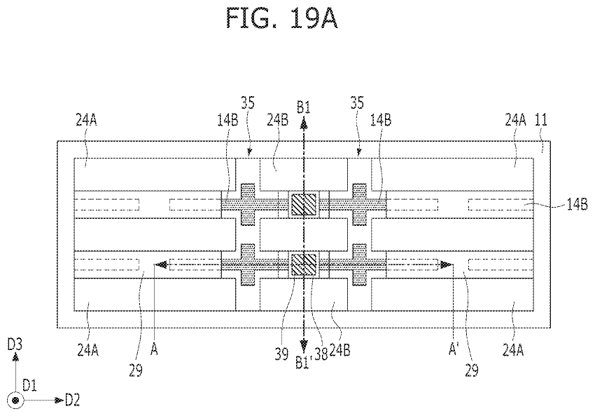

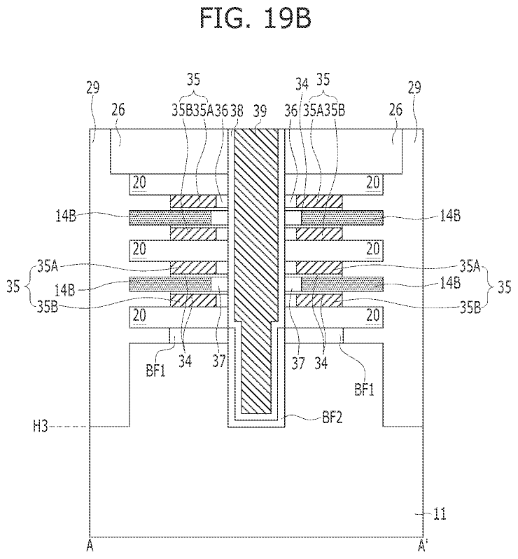

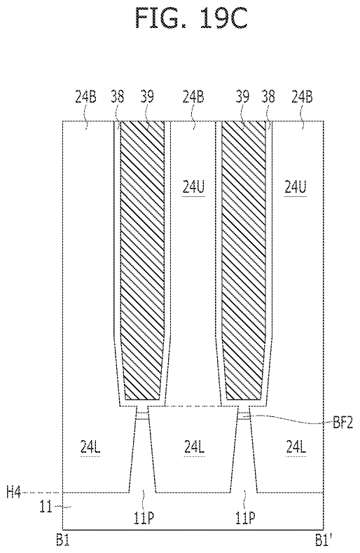

FIG. 19A is a plan view illustrating a method of forming vertical conductive lines 39, and FIG. 19B is a cross-sectional view taken along a line A-A′ shown in FIG. 19A. FIG. 19C is a cross-sectional view taken along a line B-B′ shown in FIG. 19A.

Referring to FIGS. 19A to 19C, a first capping layer 36 may be formed on one side surface of the horizontal conductive line 35. The first capping layer 36 may include silicon oxide, silicon nitride, silicon carbon oxide, an embedded air gap, or a combination thereof. A deposition process and an etch-back process of a capping material may be performed to form the first capping layer 36. While the first capping layer 36 is formed or after the first capping layer 36 is formed, a portion of the inter-level dielectric layer 34 may be removed to expose a first edge portion of each of the horizontal layers 14B.

Subsequently, a vertical conductive line 39 coupled to the first edge portion of each of the horizontal layers 14B may be formed. The vertical conductive line 39 may fill the first hole-type vertical opening 32. The vertical conductive line 39 may be commonly coupled to the horizontal layers 14B arranged in the first direction D1. The vertical conductive line 39 may include titanium nitride, tungsten, or combinations thereof. The vertical conductive line 39 may be referred to as a bit line or a vertical bit line.

Before the vertical conductive line 39 is formed, the first doped region 37 and the first contact node 38 may be formed. The first doped region 37 may be formed in the first edge portions of the horizontal layers 14B. Forming the first doped region 37 may include depositing polysilicon that is doped with an N-type impurity, performing a heat treatment, and removing the doped polysilicon. The first doped region 37 may include the impurity diffused from the doped polysilicon. According to another embodiment of the present invention, the first doped region 37 may be formed by doping an impurity.

The first contact node 38 may include doped polysilicon. The first doped region 37 may include the impurity diffused from the first contact node 38. A metal silicide layer may be further formed between the vertical conductive line 39 and the first contact node 38.

The vertical conductive line 39 may correspond to the first conductive line BL as illustrated in FIGS. 1A to 1D.

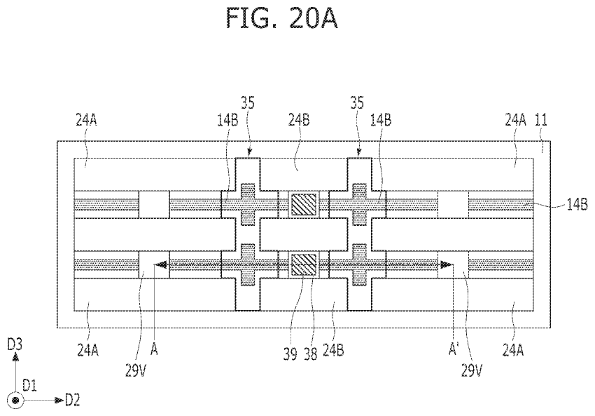

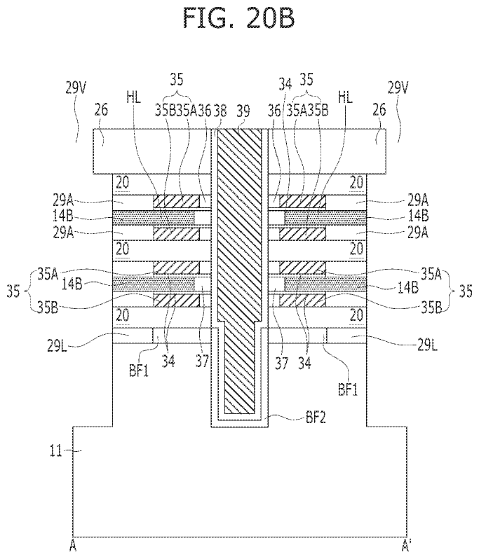

FIG. 20A is a plan view illustrating a method of forming the preliminary second hole-type vertical openings 29V, and FIG. 20B is a cross-sectional view taken along a line A-A′ shown in FIG. 20A.

Referring to FIGS. 20A and 20B, a portion of the vertical sacrificial structure 29 may be removed to form the preliminary second hole-type vertical openings 29V. One side, that is, the second edge portion of the horizontal layers 14B may be exposed by the preliminary second hole-type vertical openings 29V. After the preliminary second hole-type vertical openings 29V are formed, a preliminary second capping layer 29A may be formed on the upper and bottom surfaces of the horizontal layers 14B.

While the preliminary second capping layer 29A is formed, the lowermost level dielectric layer 29L may be formed on the side surfaces of the first passivation layers BF1 by removing a portion of the vertical sacrificial structure 29.

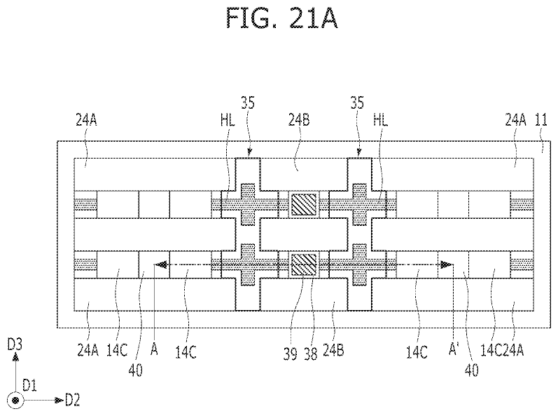

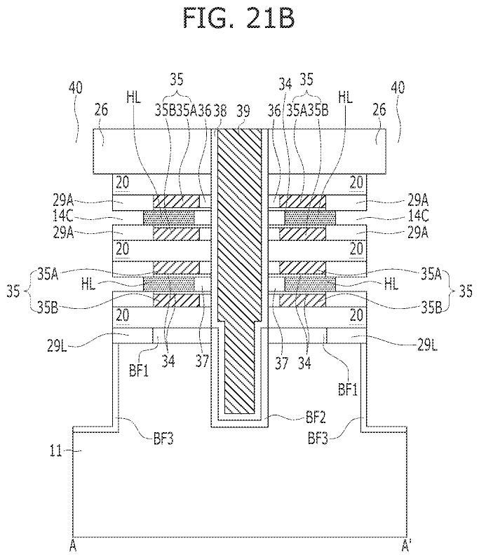

FIG. 21A is a plan view illustrating a recess method of the horizontal layers HL, and FIG. 21B is a cross-sectional view taken along a line A-A′ shown in FIG. 21A.

Referring to FIGS. 21A and 21B, a third passivation layer BF3 may be formed on the surface of the lower structure 11. The third passivation layer BF3 may include silicon oxide.

Subsequently, the second edge portion of the horizontal layers 14B may be horizontally recessed (see a reference numeral ‘14C’) in the second direction D2. As a result, the horizontal layers may remain as indicated by a reference symbol ‘HL’.

After the horizontal layers HL are formed, the preliminary second hole-type vertical openings may be expanded as indicated by a reference numeral ‘40’. Hereinafter, the expanded preliminary second hole-type vertical openings may be simply referred to as second hole-type vertical openings 40.

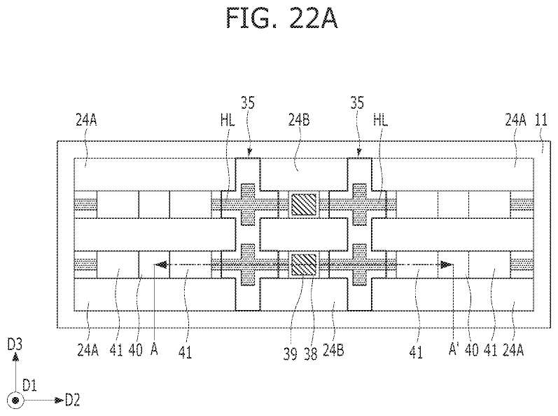

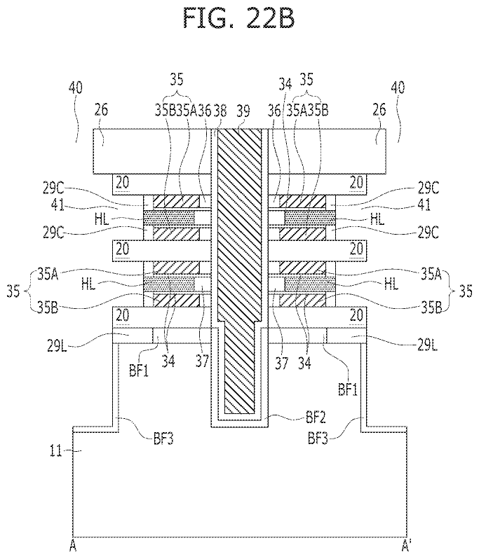

FIG. 22A is a plan view illustrating a method of forming storage openings 41, and FIG. 22B is a cross-sectional view taken along a line A-A′ shown in FIG. 22A.

Referring to FIGS. 22A and 22B, second capping layers 29C may be formed by selectively recessing the preliminary second capping layers 29A. The second capping layers 29C may include silicon oxide, silicon nitride, or a combination thereof.

After the second capping layers 29C are formed, storage openings 41 extending horizontally from the second hole-type vertical openings 40 may be formed. The storage openings 41 may be referred to as capacitor openings.

The horizontal layers HL may include a first edge and a second edge. The first edge may refer to a portion that is coupled to the first contact node 38 and the vertical conductive line 39, and the second edge may refer to a portion that is exposed by the storage openings 41.

The storage openings 41 may be disposed between the second dielectric layers 20. The second capping layers 29C may be disposed in the lower and upper portions of the horizontal layers HL, respectively.

As described above, forming the horizontal layers HL and the storage openings 41 may include forming the second hole-type vertical openings 40, recessing the horizontal layers 14B, and forming the second capping layer 29C.

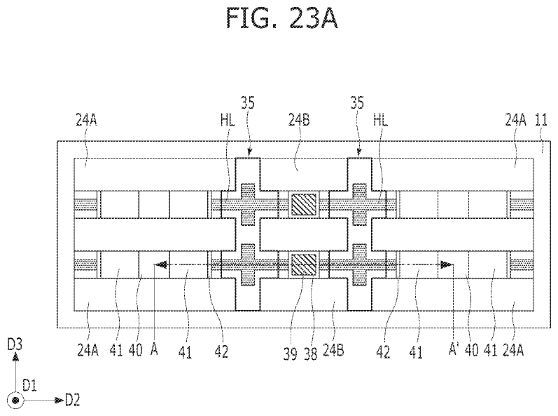

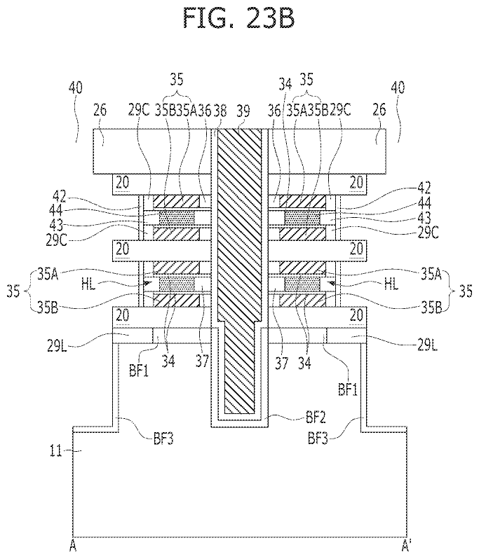

FIG. 23A is a plan view illustrating a method of forming the second contact nodes 42, and FIG. 23B is a cross-sectional view taken along a line A-A′ shown in FIG. 23A.

Referring to FIGS. 23A and 23B, second doped regions 43 may be formed in the second edges of the horizontal layers HL, respectively. Forming the second doped regions 43 may include depositing polysilicon that is doped with an N-type impurity, performing a heat treatment, and removing the doped polysilicon. The second doped regions 43 may include the impurity diffused from the doped polysilicon. According to another embodiment of the present invention, after the heat treatment, the doped polysilicon may remain.

Subsequently, the second contact nodes 42 may be formed on the second edges of the horizontal layers HL. The second contact nodes 42 may include the doped polysilicon. The second doped regions 43 may include the impurity diffused from the second contact nodes 42.

The individual horizontal layer HL may include the first doped region 37, the second doped region 43, and a channel 44 that are arranged horizontally in the second direction D2. The channels 44 may be defined between the first doped regions 37 and the second doped regions 43. The channels 44 may vertically overlap with the horizontal conductive lines 35. As illustrated in FIGS. 1A to 1D, the horizontal layers HL may have a cross shape, and the channels 44 may also have a cross shape.

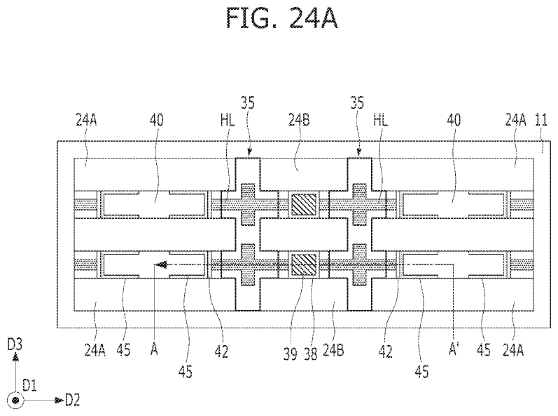

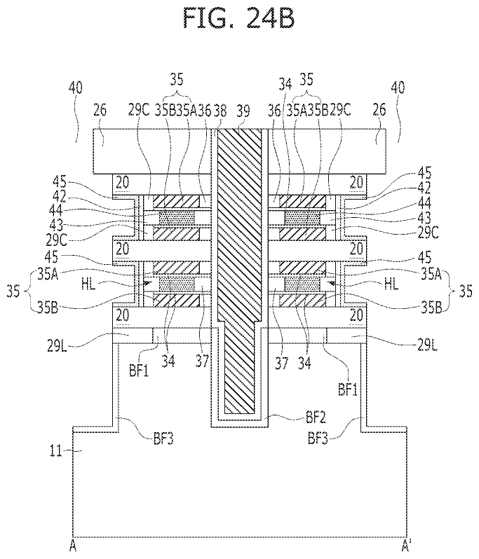

FIG. 24A is a plan view illustrating a method of forming first electrodes 45, and FIG. 24B is a cross-sectional view taken along a line A-A′ shown in FIG. 24A.

Referring to FIGS. 24A and 24B, the first electrodes 45 of the data storage element may be formed over the second contact nodes 42. The first electrodes 45 may have a horizontally oriented cylindrical shape. The first electrodes 45 may be respectively disposed in the storage openings 41. The first electrodes 45 neighboring in the second direction D2 may be spaced apart from each other by the second hole-type vertical openings 40. The first electrodes 45 neighboring in the third direction D3 may be spaced apart from each other by the second cell isolation layers 24A.

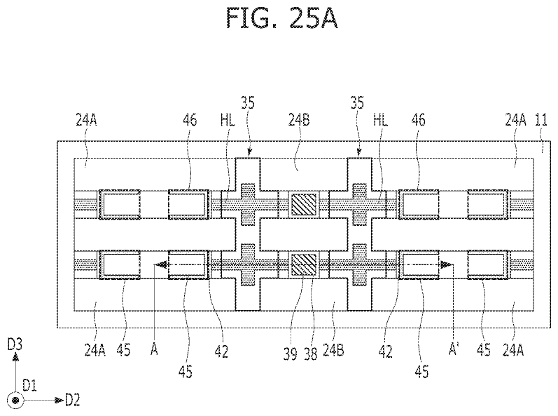

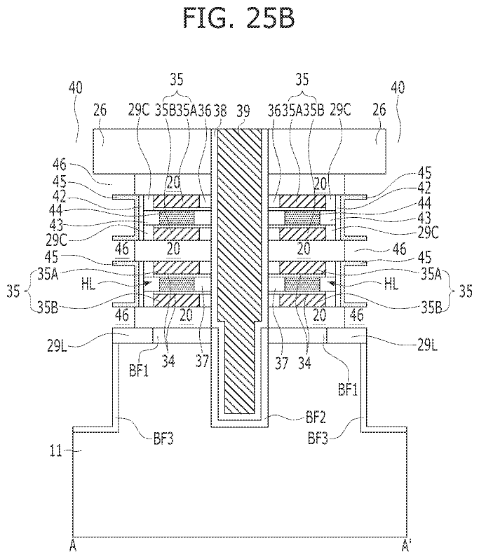

FIG. 25A is a plan view illustrating a method of exposing the outer walls of the first electrodes 45, and FIG. 25B is a cross-sectional view taken along a line A-A′ shown in FIG. 25A.

Referring to FIGS. 25A and 25B, the second dielectric layers 20 may be horizontally recessed (refer to a reference numeral 46). As a result, the outer walls of the first electrodes 45 may be exposed. The recessed second dielectric layers 20 may correspond to the inter-cell dielectric layer IL as illustrated in FIG. 3B.

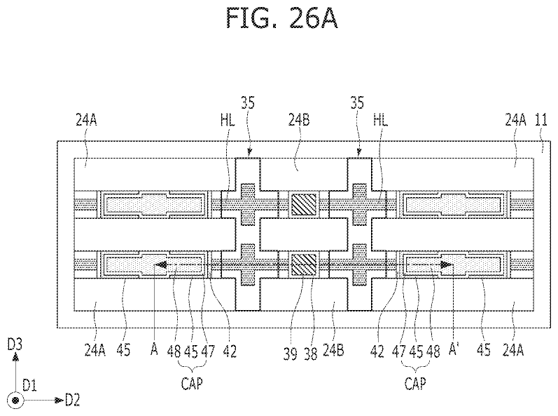

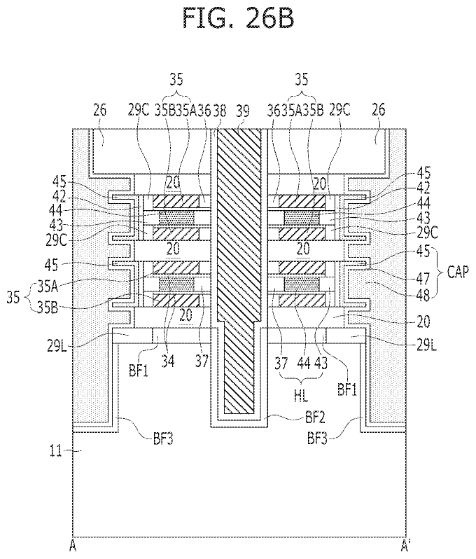

FIG. 26A is a plan view illustrating a method of forming the dielectric layer 47 and the second electrode 48, and FIG. 26B is a cross-sectional view taken along a line A-A′ shown in FIG. 26A.

Referring to FIGS. 26A and 26B, the dielectric layer 47 and the second electrode 48 may be sequentially formed over the first electrodes 45. The first electrode 45, the dielectric layer 47 and the second electrode 48 may form a data storage element CAP.

Each first electrode 45 may include an inner space and a plurality of outer surfaces, and the inner space of the first electrode 45 may include a plurality of inner surfaces. The outer surfaces of the first electrode 45 may include a vertical outer surface and a plurality of horizontal outer surfaces. The vertical outer surface of the first electrode 45 may extend vertically in the first direction D1, and the horizontal outer surfaces of the first electrode 45 may horizontally extend in the second direction D2 or the third direction D3. The inner space of the first electrode 45 may be a three-dimensional space. The dielectric layer 47 may conformally cover the inner and outer surfaces of the first electrode 45. The second electrode 48 may be disposed in the inner space of the first electrode 45 over the dielectric layer 47. Some of the outer surfaces of the first electrode 45 may be electrically connected to the second doped region 43 of the horizontal layer HL.

The first electrode 45 may have a cylindrical shape. The cylindrical shape of the first electrode 45 may include the cylindrical inner surfaces and cylindrical outer surfaces. Some of the cylindrical outer surfaces of the first electrode 45 may be electrically connected to the second doped region 43 of the horizontal layer HL. The dielectric layer 47 and the second electrode 48 may be disposed on the cylindrical inner surfaces of the first electrode 45. The second electrode 48 may extend vertically in the first direction D1.

The first electrode 45 and the second electrode 48 may include a metal, a noble metal, a metal nitride, a conductive metal oxide, a conductive noble metal oxide, a metal carbide, a metal silicide, or a combination thereof. For example, the first electrode 45 and the second electrode 48 may include titanium (Ti), titanium nitride (TiN), tantalum (Ta), tantalum nitride (TaN), tungsten (W), tungsten nitride (WN), ruthenium (Ru), ruthenium oxide (RuO₂), iridium (Ir), iridium oxide (IrO₂), platinum (Pt), molybdenum (Mo), molybdenum oxide (MoO), a titanium nitride/tungsten (TiN/W) stack, a tungsten nitride/tungsten (WN/W) stack, or a combination thereof. The second electrode 48 may include a combination of a metal-based material and a silicon-based material. For example, the second electrode 48 may be a stack of titanium nitride/silicon germanium/tungsten nitride (TiN/SiGe/WN). In the titanium nitride/silicon germanium/tungsten nitride (TiN/SiGe/WN) stack, silicon germanium may be a gap-fill material that fills the inner space of the first electrode 45, and titanium nitride (TiN) may serve as the second electrode 48 of a data storage element CAP, and tungsten nitride may be a low-resistance material.

The dielectric layer 47 may be referred to as a capacitor dielectric layer or a memory layer. The dielectric layer 47 may include silicon oxide, silicon nitride, a high-k material, a ferroelectric material, an anti-ferroelectric material, or a combination thereof. The dielectric layer 47 may include high-k materials such as hafnium oxide (HfO₂), zirconium oxide (ZrO₂), aluminum oxide (Al₂O₃), lanthanum oxide (La₂O₃), titanium oxide (TiO₂), tantalum oxide (Ta₂O₅), niobium oxide (Nb₂O₅) or strontium titanium oxide (SrTiO₃). The dielectric layer 45 may include a ZA (ZrO₂/Al₂O₃) stack, a ZAZ (ZrO₂/Al₂O₃/ZrO₂) stack, a ZAZA (ZrO₂/Al₂O₃/ZrO₂/Al₂O₃) stack, a ZAZAZ (ZrO₂/Al₂O₃/ZrO₂/Al₂O₃/ZrO₂) stack, an HA (HfO₂/Al₂O₃) stack, an HAH (HfO₂/Al₂O₃/HfO₂) stack, a HAHA (HfO₂/Al₂O₃/HfO₂/Al₂O₃) stack, or a HAHAH (HfO₂/Al₂O₃/HfO₂/Al₂O₃/HfO₂) stack.

According to another embodiment of the present invention, an interface control layer for improving leakage current may be further formed between the first electrode 45 and the dielectric layer 47. The interface control layer may include titanium oxide (TiO₂), tantalum oxide (Ta₂O₅), niobium oxide (Nb₂O₅), niobium nitride (NbN), or a combination thereof. An interface control layer may also be formed between the second electrode 45 and the dielectric layer 47.

According to the above-described embodiment of the present invention, since the bottom surfaces of the first and second cell isolation layers 24A and 24B are disposed at a lower level than the bottom surfaces of the vertical conductive line 39 and the data storage element CAP, it is possible to prevent a bunker that may occur while the vertical conductive line 39 and the data storage element CAP are formed.

Also, since a cross-shaped horizontal layer HL is formed, it is possible to improve the channel width and the bridge between the memory cells.

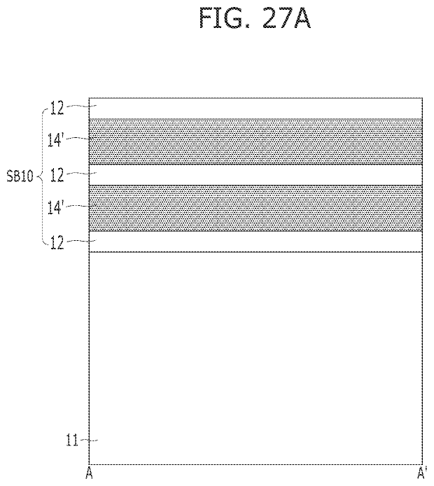

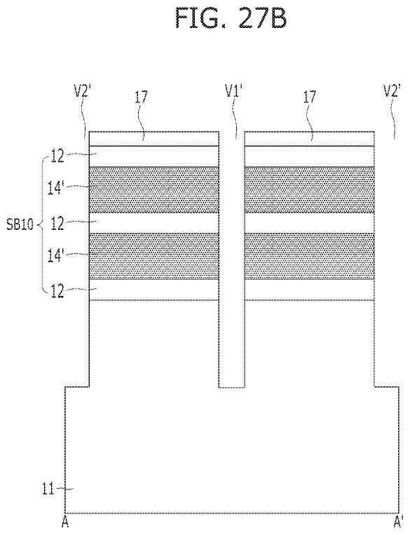

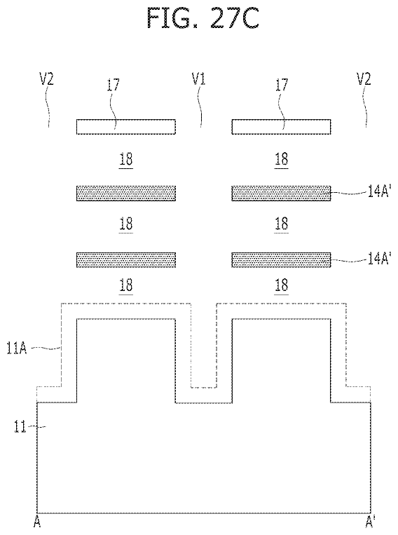

FIGS. 27A to 27C are cross-sectional views illustrating a method for fabricating a semiconductor device in accordance with another embodiment of the present invention.

Referring to FIG. 27A, a stack body SB10 may be formed over the lower structure 11. The stack body SB10 may include an alternating stack of first semiconductor layers and second semiconductor layers. For example, the alternating stack may include a plurality of silicon germanium layers 12 and a plurality of monocrystalline silicon layers 14′ that are alternately stacked by an epitaxial growth process. The silicon germanium layers 12 may be sacrificial layers, and the monocrystalline silicon layers 14′ may be recess target layers. The silicon germanium layers 12 may correspond to the first layers 12A or the third layers 12B shown in FIG. 4B, and the monocrystalline silicon layers 14′ may correspond to the fourth layers 14 shown in FIG. 4B. Unlike the stack body SB shown in FIG. 4B, the stack body SB10 may include an alternating stack of silicon germanium layers 12 and monocrystalline silicon layers 14′.

Subsequently, a series of the processes as illustrated in FIGS. 4A to 5B may be performed. For example, sacrificial isolation openings 15A and 15B and sacrificial isolation layers 16A and 16B may be formed in the stack body SB10.

Subsequently, referring to FIG. 27B, a hard mask layer pattern 17 may be formed over the stack body SB10.

Subsequently, the stack body SB may be etched using the hard mask layer pattern 17 as an etch barrier. As a result, a plurality of first and second sacrificial vertical openings V1′ and V2′ may be formed in the stack body SB10.

Referring to FIG. 27C, the preliminary horizontal layers 14A′ and the horizontal recesses 18 may be formed. The preliminary horizontal layers 14A′ and the horizontal recesses 18 may be formed by a recess process of the silicon germanium layers 12 and the monocrystalline silicon layers 14′ shown in FIG. 27B. After the silicon germanium layers 12 are removed, a recess process of the monocrystalline silicon layers 14′ may be performed. The preliminary horizontal layers 14A′ may correspond to the preliminary horizontal layers 14A shown in FIG. 7B.

To recess the silicon germanium layers 12, a wet etching process or a dry etching process may be used. The silicon germanium layers 12 may be etched using an etchant or an etching gas having a selectivity with respect to the monocrystalline silicon layers 14′.

The recess process of the monocrystalline silicon layers 14′ for forming the preliminary horizontal layers 14A′ may use, for example, HSC1 (Hot SC-1). HSC1 may include a mixed solution in which ammonium hydroxide (NH₄OH), hydrogen peroxide (H₂O₂) and water (H₂O) are mixed at a ratio of approximately 1:4:20. The monocrystalline silicon layers 14′ may be selectively etched using HSC1.

After the preliminary horizontal layers 14A′ are formed, the first and second sacrificial vertical openings may be expanded as indicated by reference symbols ‘V1’ and ‘V2’. The preliminary horizontal layers 14A′ may be spaced apart from each other by the first and second sacrificial vertical openings V1 and V2 in the second direction D2. The preliminary horizontal layers 14A′ may have a shape in which a plurality of cross shapes are merged in the third direction D3. While the preliminary horizontal layers 14A′ are formed, the surface of the lower structure 11 may be recessed to a certain depth (see a reference numeral ‘11A’). As a result, the depths of the first and second sacrificial vertical openings V1 and V2 may be increased.

Subsequently, a series of the processes shown in FIGS. 8A to 26B may be performed.

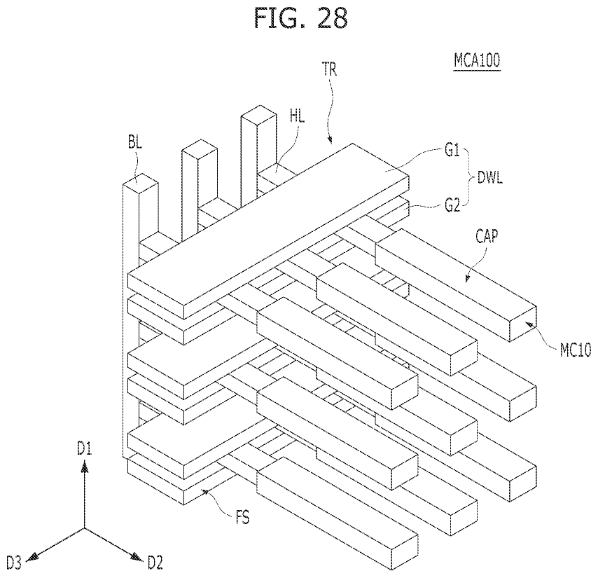

FIGS. 28 to 30 are perspective views illustrating memory cell arrays in accordance with embodiments of the present invention. The memory cell arrays MCA100, MCA200, and MCA300 may be similar to the memory cell array MCA shown in FIG. 3A. Hereinafter, as for the detailed description of the constituent elements also appearing in FIG. 3A, the above-described embodiments may be referred to.

Referring to FIG. 28, the memory cell array MCA100 may include a plurality of memory cells MC10.

The memory cell array MCA100 may include a three-dimensional array of memory cells MC10. The three-dimensional array of memory cells MC10 may include a column array of memory cells MC10 and a row array of memory cells MC10. The column array of memory cells MC10 may include a plurality of memory cells MC10 that are stacked in the first direction D1, and the row array of memory cells MC10 may include a plurality of memory cells MC10 that are horizontally arranged in the second direction D2 and the third direction D3.

The individual memory cell MC10 may include a first conductive line BL, a switching element TR, and a data storage element CAP. As for the detailed descriptions on the first conductive line BL and the data storage element CAP, the above-described embodiments may be referred to.

The switching element TR may include a horizontal layer HL and a second conductive line DWL. The horizontal layer HL may extend in the second direction D2. The second conductive line DWL may extend in the third direction D3.

The second conductive line DWL may have a double structure.

For example, the second conductive line DWL may include an upper horizontal line G1 and a lower horizontal line G1 that face each other with the horizontal layer HL interposed therebetween. As illustrated in FIG. 3B, an inter-level dielectric layer GD may be formed on the upper and bottom surfaces of the horizontal layer HL.

Each of the upper horizontal line G1 and the lower horizontal line G2 may include a pair of flat sidewalls FS extending in the third direction D3. The flat sidewall FS may refer to a vertical sidewall. The flat sidewall FS may have a linear shape extending in the third direction D3.

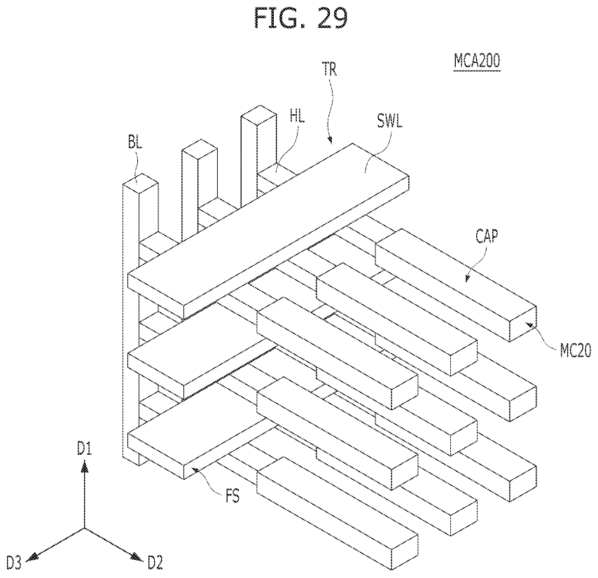

Referring to FIG. 29, the memory cell array MCA200 may include a plurality of memory cells MC20.

The memory cell array MCA200 may include a three-dimensional array of memory cells MC20. The three-dimensional array of memory cells MC20 may include a column array of memory cells MC20 and a row array of memory cells MC20. The column array of memory cells MC20 may include a plurality of memory cells MC20 that are stacked in the first direction D1, and the row array of memory cells MC20 may include a plurality of memory cells MC20 that are horizontally arranged in the second direction D2 and the third direction D3.

The individual memory cell MC20 may include a first conductive line BL, a switching element TR, and a data storage element CAP. As for the detailed description on the first conductive line BL and the data storage element CAP, the above-described embodiments may be referred to.

The switching element TR may include a horizontal layer HL and a second conductive line SWL. The horizontal layer HL may extend in the second direction D2. The second conductive line SWL may extend in the third direction D3.

The second conductive line SWL may have a single structure.

For example, the second conductive line SWL may be disposed over the horizontal layer HL. Referring to FIG. 3B, an inter-level dielectric layer GD may be formed between the top surface of the horizontal layer HL and the second conductive line SWL. According to another embodiment of the present invention, the second conductive line SWL may be disposed below the horizontal layer HL.

The second conductive line SWL may include a pair of flat sidewalls FS extending in the third direction D3. The flat sidewall FS may refer to a vertical sidewall.

According to another embodiment of the present invention, the second conductive line SWL may include a channel overlapping portion WLP and a channel non-overlapping portion NOL, as illustrated in FIG. 1C.

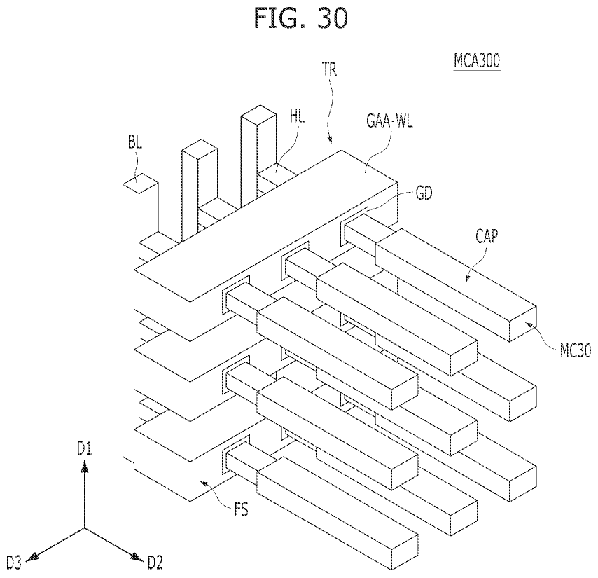

Referring to FIG. 30, the memory cell array MCA300 may include a plurality of memory cells MC30.

The memory cell array MCA300 may include a three-dimensional array of memory cells MC30. The three-dimensional array of memory cells MC30 may include a column array of memory cells MC30 and a row array of memory cells MC30. The column array of memory cells MC30 may include a plurality of memory cells MC30 that are stacked in the first direction D1, and the row array of memory cells MC30 may include a plurality of memory cells MC30 that are horizontally arranged in the second direction D2 and the third direction D3.

The individual memory cell MC30 may include a first conductive line BL, a switching element TR, and a data storage element CAP. As for the detailed description on the first conductive line BL and the data storage element CAP, the above-described embodiments may be referred to.

The switching element TR may include a horizontal layer HL and a second conductive line GAA-WL. The horizontal layer HL may extend in the second direction D2. The second conductive line GAA-WL may extend in the third direction D3.

The second conductive line GAA-WL may have a gate all around structure GAA. For example, the second conductive line GAA-WL may extend in the third direction D3 while surrounding the horizontal layers HL. An inter-level dielectric layer GD may be formed between the horizontal layer HL and the second conductive line GAA-WL. The inter-level dielectric layer GD may surround the individual horizontal layers HL.

The second conductive line GAA-WL may include a pair of flat sidewalls FS extending in the third direction D3. The flat sidewall FS may refer to a vertical sidewall.

According to the embodiment of the present invention, since the bottom surfaces of the cell isolation layers are lower than the bottom surfaces of the vertical conductive lines, it is possible to prevent a bunker that may occur while a vertical conductive line and a data storage element are formed.

According to the embodiment of the present invention, it is possible to increase the structural stability of memory cells by forming supporters below the vertical conductive lines and the data storage elements.

According to the embodiment of the present invention, low power consumption and high integration of 3D memory cells may be realized.

While the present invention has been described with respect to the specific embodiments, it will be apparent to those skilled in the art that various changes and modifications may be made without departing from the spirit and scope of the invention as defined in the following claims. Furthermore, the embodiments may be combined to form additional embodiments.

For example, while the described embodiments employ horizontally extending and vertically extending elements or layers, the present invention disclosure is not limited thereto. In some variations of the present embodiments the second and third directions D2 and D3 may be referred to as lateral directions defining a lateral plane while the third direction D3 may be an upright direction extending at an orthogonal or substantially orthogonal angle above the lateral plane.

What is claimed is:

1. A method for fabricating a semiconductor device, the method comprising:
forming a stack body including a plurality of recess target layers over a lower structure;
forming sacrificial isolation openings in the stack body;
forming sacrificial isolation layers in the sacrificial isolation openings;
forming sacrificial vertical openings having bottom surfaces disposed at a lower level than bottom surfaces of the sacrificial isolation openings in the stack body between the sacrificial isolation layers;
forming preliminary horizontal layers by recessing the recess target layers through the sacrificial vertical openings;
forming sacrificial pillar structures that fill the sacrificial vertical openings;
forming cell isolation openings by removing the sacrificial isolation layers;
forming horizontal layers by trimming the preliminary horizontal layers through the cell isolation openings; and
forming cell isolation layers that fill the cell isolation openings.

2. The method of claim 1, wherein bottom surfaces of the cell isolation layers are disposed at a lower level than bottom surfaces of the sacrificial pillar structures.

3. The method of claim 1, wherein while the horizontal layers are formed,
bottom surfaces of the isolation openings are lowered and supporters are formed below the sacrificial pillar structures.

4. The method of claim 3, wherein the lowered bottom surfaces of the isolation openings are disposed at a lower level than the bottom surfaces of the sacrificial pillar structures.

5. The method of claim 1, wherein the forming of the preliminary horizontal layers includes
lowering the bottom surfaces of the sacrificial vertical openings, and
the lowered bottom surfaces of the sacrificial vertical openings are disposed at a higher level than the bottom surfaces of the sacrificial isolation layers.

6. The method of claim 1, wherein the recess target layers include a monocrystalline silicon layer.

7. The method of claim 1, further comprising:
before the forming of the cell isolation layers,
forming horizontal layer level spacers on side surfaces of the horizontal layers.

8. The method of claim 1, wherein the forming the stack body including the recess target layers includes:
alternately forming a plurality of sacrificial layers and the recess target layers.

9. A method for fabricating a semiconductor device, the method comprising:
forming a stack body including a plurality of sub-stacks over a lower structure;
forming sacrificial isolation openings in the stack body;
forming sacrificial isolation layers in the sacrificial isolation openings;
forming sacrificial vertical openings having bottom surfaces disposed at lower levels than the sacrificial isolation openings in the stack body between the sacrificial isolation layers;
forming sacrificial pillar structures that fill the sacrificial vertical openings;
forming cell isolation openings by removing the sacrificial isolation layers;
expanding the cell isolation openings to form supporters that support the sacrificial pillar structures; and
forming cell isolation layers that fill the expanded cell isolation openings.

10. The method of claim 9, wherein bottom surfaces of the cell isolation layers are disposed at a lower level than the bottom surfaces of the sacrificial vertical openings and the sacrificial pillar structures.

11. The method of claim 9, wherein each of the expanded cell isolation openings includes:
a lower region disposed between the supporters; and
an upper region disposed between the sacrificial pillar structures, and
a horizontal width of the lower region is formed to be greater than a horizontal width of the upper region.

12. The method of claim 9, further comprising:
replacing the sub-stacks with cell molds, after the forming of the sacrificial vertical openings.

13. The method of claim 12, wherein the sub-stacks are formed by alternating sacrificial layers and recess target layers, and
each of the cell molds includes:
a preliminary horizontal layer;
a first dielectric layer covering the preliminary horizontal layer; and
a second dielectric layer disposed in upper and lower portions of the first dielectric layer, and
wherein the preliminary horizontal layers are formed by recessing the recess target layers, and
the first and second dielectric layers are formed by a replacement process of replacing the sacrificial layers with dielectric materials.

14. The method of claim 13, further comprising:
trimming preliminary horizontal layers of the cell molds to form horizontal layers;
trimming the first dielectric layers of the cell molds to form first dielectric layer patterns;
replacing the first dielectric layer patterns with horizontal conductive lines;
forming a vertical conductive line that is coupled to first edges of the horizontal layers; and
forming data storage elements that are respectively coupled to second edges of the horizontal layers.

15. The method of claim 13, wherein the first dielectric layers include silicon nitride, and
the second dielectric layers include silicon oxide, and
the recess target layers include a monocrystalline silicon layer.
